(19) United States
(12) Patent Application Publication
(10) Pub. No.: US 2023/0371365 A1
(43) Pub. Date: Nov. 16, 2023

(54) Organic Light Emitting Device and Display Device

(71) Applicant: BOE Technology Group Co., Ltd., Beijing (CN)

(72) Inventors: Kun MA, Beijing (CN); Lei CHEN, Beijing (CN); Dan WANG, Beijing (CN)

(21) Appl. No.: 17/426,652

(22) PCT Filed: Jan. 26, 2021
(86) PCT No.: PCT/CN2021/073704

§ 371 Date: Jul. 29, 2021

(51) Int. Cl. H10K 85/60; C09K 11/06

(52) U.S. Cl. CPC H10K 85/633; C09K 11/06; H10K 85/636; H10K 50/181

(57) ABSTRACT

Provided is an organic light emitting device, including a first electrode, a second electrode, and an emitting layer disposed between the first electrode and the second electrode. An electron blocking layer and a hole transport layer are disposed between the emitting layer and the first electrode. The electron blocking layer is located between the hole transport layer and the emitting layer. The material of the electron blocking layer includes a compound having the following structural formula:

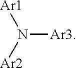

### TECHNICAL FIELD

The present disclosure relates to but is not limited to the technical field of display, in particular to an organic light emitting device and a display device.

### BACKGROUND

As a novel flat panel display device, the Organic Light Emitting Device (OLED) attracts increasingly more attention. The OLED is an active light emitting device, which has the advantages of high brightness, color saturation, ultra-thinness, wide view, relatively low power consumption, extremely high response speed, and flexibility.

The OLED includes an anode, a cathode, and an emitting layer disposed between the anode and the cathode. The light emitting principle of the OLED is respectively injecting holes and electrons into the emitting layer from the anode and the cathode such that when the electrons and the holes meet in the emitting layer, the electrons and the holes combine to produce excitons and these excitons emit light when switching from an excited state to a ground state.

### SUMMARY

The following is a brief description of the subject matter described in detail in the present disclosure. This brief description is not intended to limit the scope of protection of the claims.

The embodiments of the present disclosure provide an organic light emitting device and a display device.

In one aspect, an embodiment of the present disclosure provides an organic light emitting device, including a first electrode, a second electrode, and an emitting layer disposed between the first electrode and the second electrode, wherein an electron blocking layer and a hole transport layer are disposed between the emitting layer and the first electrode; and the electron blocking layer is located between the hole transport layer and the emitting layer. The material of the electron blocking layer includes a compound having the following structural formula:

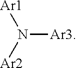

Ar1 to Ar3 are separately one of a substituted or unsubstituted aryl group with 6 to 40 carbon atoms, a substituted or unsubstituted heteroaryl group with 3 to 40 carbon atoms, a substituted or unsubstituted alkyl group with 1 to 20 carbon atoms, and a substituted or unsubstituted cycloalkyl group with 1 to 30 carbon atoms.

At least one of Ar1 to Ar3 is connected to the following structure:

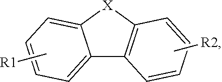

X is one of carbon (C), nitrogen (N), sulfur (S), and oxygen (O).

R1 and R2 are separately one of hydrogen, deuterium, an alkyl group with 1 to 30 carbon atoms, a substituted or unsubstituted cycloalkyl group with 3 to 40 carbon atoms, a substituted or unsubstituted alkenyl group with 2 to 30 carbon atoms, a substituted or unsubstituted alkynyl group with 2 to 30 carbon atoms, a substituted or unsubstituted heteroalkyl group with 2 to 30 carbon atoms, a substituted or unsubstituted arylalkyl group with 7 to 30 carbon atoms, a substituted or unsubstituted aryl group with 6 to 30 carbon atoms, and a substituted or unsubstituted heteroaryl group with 2 to 30 carbon atoms.

The material of the hole transport layer includes a compound having the following structural formula:

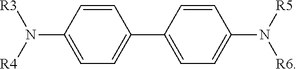

R3 to R6 are separately one of deuterium, a cyano group, a nitro group, halogen, a hydroxyl group, a substituted or unsubstituted alkyl group with 1 to 30 carbon atoms, a substituted or unsubstituted cycloalkyl group with 1 to 20 carbon atoms, a substituted or unsubstituted alkenyl group with 2 to 30 carbon atoms, a substituted or unsubstituted alkynyl with 2 to 24 carbon atoms, a substituted or unsubstituted heteroalkyl group with 2 to 30 carbon atoms, a substituted or unsubstituted arylalkyl group with 7 to 30 carbon atoms, a substituted or unsubstituted aryl group with 6 to 30 carbon atoms, a substituted or unsubstituted heteroaryl group with 2 to 30 carbon atoms, a substituted or unsubstituted heteroaryl group with 3 to 30 carbon atoms, a substituted or unsubstituted alkoxy group with 1 to 30 carbon atoms, a substituted or unsubstituted alkylamino group with 1 to 30 carbon atoms, a substituted or unsubstituted arylamino group with 6 to 30 carbon atoms, a substituted or unsubstituted arylalkylamino group with 6 to 30 carbon atoms, a substituted or unsubstituted heteroarylamino group with 2 to 24 carbon atoms, a substituted or unsubstituted alkylmethylsilyl group with 1 to 30 carbon atoms, a substituted or unsubstituted arylmethylsilyl group with 6 to 30 carbon atoms, and a substituted or unsubstituted aryloxy group with 6 to 30 carbon atoms.

In some exemplary embodiments, Ar1, Ar2, and Ar3 are at least partially the same or different from each other, and R1 and R2 are the same or different.

In some exemplary embodiments, the electron blocking layer and the hole transport layer satisfy the following condition:

0.3 eV≤|HOMO_{EBL}|−|HOMO_{HTL}|≤0.7 eV.

HOMO_{EBL} is the Highest Occupied Molecular Orbital (HOMO) energy level of the electron blocking layer, and HOMO_{HTL} is the HOMO energy level of the hole transport layer.

In some exemplary embodiments, the HOMO energy level of the electron blocking layer is about −5.4 eV to −6.2 eV, and the HOMO energy level of the hole transport layer is about −5.3 eV to −5.6 eV.

In some exemplary embodiments, wherein the electron blocking layer and the hole transport layer further satisfy the following condition:

0.3 eV≤LUMO_{HTL}−LUMO_{EBL}≤0.8 eV.

LUMO_{EBL} is the Lowest Unoccupied Molecular Orbital (LUMO) energy level of the electron blocking layer, and LUMO_{HTL} is the LUMO energy level of the hole transport layer.

In some exemplary embodiments, the LUMO energy level of the electron blocking layer is about −2.2 eV to −2.4 eV, and the LUMO energy level of the hole transport layer is about −2.2 eV to −2.5 eV.

In some exemplary embodiments, the material of the electron blocking layer includes one or more of compounds having the following structural formulas:

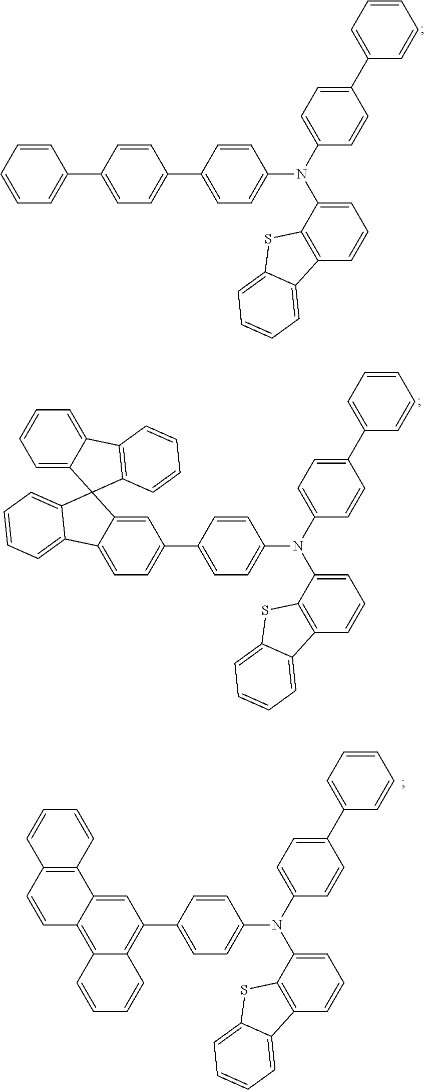 [SMILES: c1ccc(-c2ccc(-c3ccc(N(c4ccc(-c5ccccc5)cc4)c4cccc5c4sc4ccccc45)cc3)cc2)cc1 ; c1ccc(-c2ccc(N(c3ccc(-c4ccc5c(c4)C4(c6ccccc6-c6ccccc64)c4ccccc4-5)cc3)c3cccc4c3sc3ccccc34)cc2)cc1 ; c1ccc(-c2ccc(N(c3ccc(-c4cc5c6ccccc6ccc5c5ccccc45)cc3)c3cccc4c3sc3ccccc34)cc2)cc1]

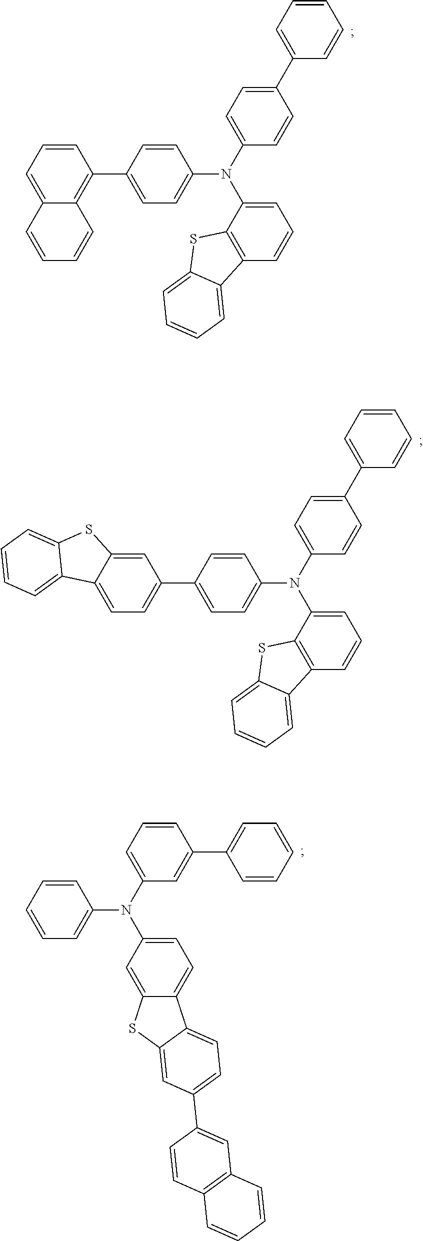 [SMILES: c1ccc(-c2ccc(N(c3ccc(-c4cccc5ccccc45)cc3)c3cccc4c3sc3ccccc34)cc2)cc1 ; c1ccc(-c2ccc(N(c3ccc(-c4ccc5c(c4)sc4ccccc45)cc3)c3cccc4c3sc3ccccc34)cc2)cc1 ; c1ccc(-c2cccc(N(c3ccccc3)c3ccc4c(c3)sc3cc(-c5ccc6ccccc6c5)ccc34)c2)cc1]

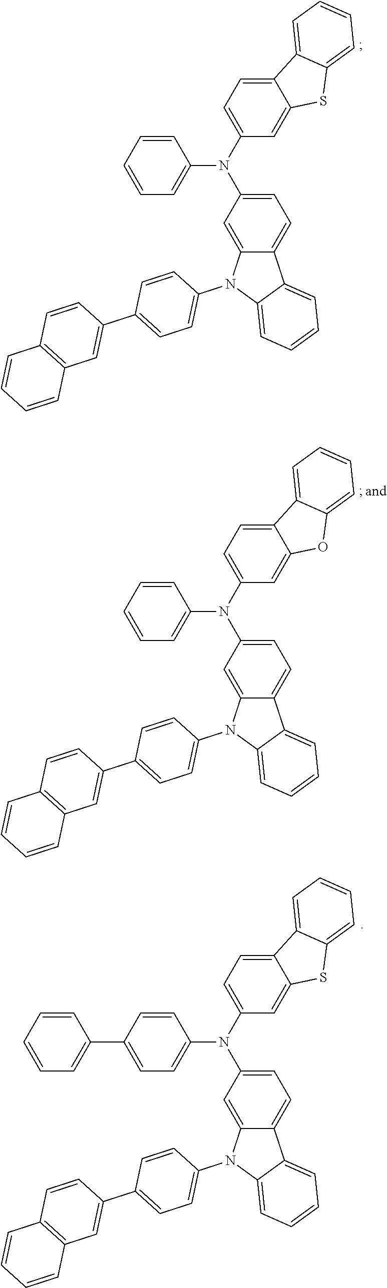 [SMILES: c1ccc(N(c2ccc3c(c2)sc2ccccc23)c2ccc3c4ccccc4n(-c4ccc(-c5ccc6ccccc6c5)cc4)c3c2)cc1 ; c1ccc(N(c2ccc3c(c2)oc2ccccc23)c2ccc3c4ccccc4n(-c4ccc(-c5ccc6ccccc6c5)cc4)c3c2)cc1 ; c1ccc(-c2ccc(N(c3ccc4c(c3)sc3ccccc34)c3ccc4c5ccccc5n(-c5ccc(-c6ccc7ccccc7c6)cc5)c4c3)cc2)cc1]

In some exemplary embodiments, the material of the hole transport layer includes one or more of compounds having the following structural formulas:

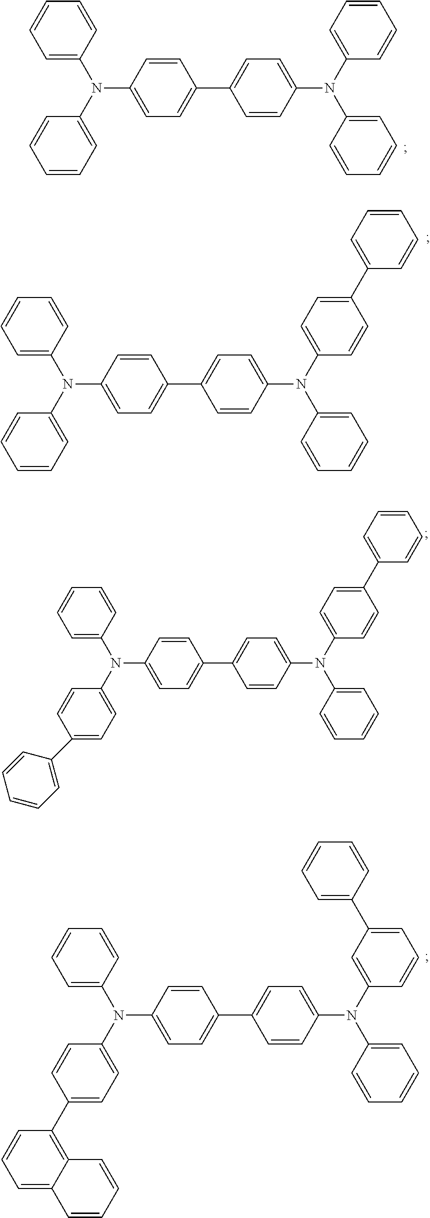

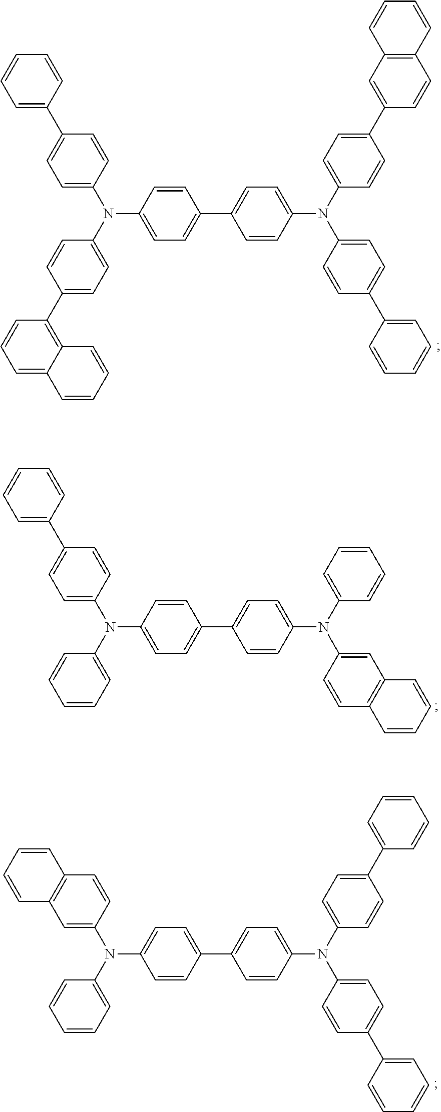 [SMILES: c1ccc(-c2ccc(N(c3ccc(-c4ccc(N(c5ccc(-c6ccccc6)cc5)c5ccc(-c6cccc7ccccc67)cc5)cc4)cc3)c3ccc(-c4ccc5ccccc5c4)cc3)cc2)cc1 ; c1ccc(-c2ccc(N(c3ccccc3)c3ccc(-c4ccc(N(c5ccccc5)c5ccc6ccccc6c5)cc4)cc3)cc2)cc1 ; c1ccc(-c2ccc(N(c3ccc(-c4ccccc4)cc3)c3ccc(-c4ccc(N(c5ccccc5)c5ccc6ccccc6c5)cc4)cc3)cc2)cc1]

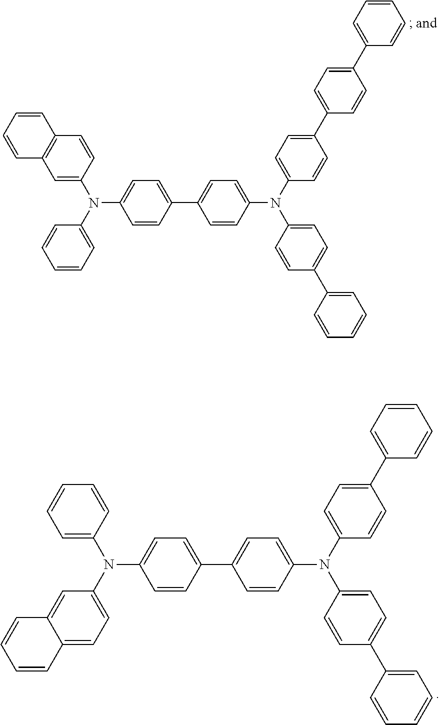 [SMILES: c1ccc(-c2ccc(-c3ccc(N(c4ccc(-c5ccccc5)cc4)c4ccc(-c5ccc(N(c6ccccc6)c6ccc7ccccc7c6)cc5)cc4)cc3)cc2)cc1 ; c1ccc(-c2ccc(N(c3ccc(-c4ccccc4)cc3)c3ccc(-c4ccc(N(c5ccccc5)c5ccc6ccccc6c5)cc4)cc3)cc2)cc1]

In some exemplary embodiments, the emitting layer is a red light emitting layer.

In some exemplary embodiments, the electron blocking layer has a thickness of about 3 nm to 10 nm.

In another aspect, an embodiment of the present disclosure provides a display device, including the organic light emitting device.

In some exemplary embodiments, the display device includes a plurality of organic light emitting devices of different colors, and electron blocking layers of the plurality of organic light emitting devices are independent of each other.

In some exemplary embodiments, the display device includes a first organic light emitting device emitting red light, a second organic light emitting device emitting green light, and a third organic light emitting device emitting blue light.

In some exemplary embodiments, the electromigration of an emitting layer of the third organic light emitting device is greater than the electromigration of an emitting layer of the first organic light emitting device, and the electromigration of the emitting layer of the first organic light emitting device is greater than the electromigration of an emitting layer of the second organic light emitting device; and the hole mobility of the emitting layer of the second organic light emitting device is greater than the hole mobility of the emitting layer of the first organic light emitting device, and the hole mobility of the emitting layer of the first organic light emitting device is greater than the hole mobility of the emitting layer of the third organic light emitting device.

In some exemplary embodiments, a startup voltage of the third organic light emitting device is greater than a startup voltage of the first organic light emitting device, and the startup voltage of the first organic light emitting device is greater than a startup voltage of the second organic light emitting device.

In some exemplary embodiments, the luminance efficiency of the second organic light emitting device is greater than the luminance efficiency of the first organic light emitting device, and the luminance efficiency of the first organic light emitting device is greater than the luminance efficiency of the third organic light emitting device.

After reading and understanding of the drawings and the detailed description, other aspects may be understood.

### BRIEF DESCRIPTION OF DRAWINGS

The drawings are used to provide a further understanding of the technical solution of the present disclosure and constitute a part of the description, and are used together with the embodiments of the present disclosure to explain the technical solution of the present disclosure without limiting the technical solution of the present disclosure. The shape and size of at least one component in the drawings do not reflect the actual scale, and are only intended to schematically describe the content of the present disclosure.

FIG. 1 is a schematic diagram of a structure of a display device.

FIG. 2 is a schematic diagram of a planar structure of a display base plate.

FIG. 3 is an equivalent circuit diagram of a pixel drive circuit.

FIG. 4 is a schematic diagram of a sectional structure of a display base plate.

FIG. 5 is a curve graph of voltage-current densities of light emitting devices of RGB three colors.

FIG. 6 is a schematic diagram of a structure of an OLED according to at least one embodiment of the present disclosure.

FIG. 7 is a schematic diagram of an energy level relationship of an OLED according to at least one embodiment of the present disclosure.

FIG. 8 is a schematic diagram of a structure of another OLED according to at least one embodiment of the present disclosure.

FIG. 9 is a curve graph of voltage-current densities of the light emitting devices of RGB three colors according to at least one embodiment of the present disclosure.

### DETAILED DESCRIPTION

The embodiments herein may be implemented in a plurality of different modes. It is easy for those skilled in the art to understand the fact that the embodiments and content may be changed into various forms without departing from the purpose and scope of the present disclosure. Therefore, the present disclosure should not be interpreted as being limited to the content recited in the following embodiments. Without conflict, the embodiments in the present disclosure and the features in the embodiments may be randomly combined with each other.

In the drawings, sometimes for clarity, the size of the constituent elements, and the thickness of the layer or the area may be exaggerated. Therefore, any embodiment of the present disclosure is not necessarily limited to the dimensions illustrated in the drawings, and the shape and size of the components in the drawings do not reflect the actual scale. In addition, the drawings schematically illustrate ideal examples, and any embodiment of the present disclosure is not limited to the shape, numerical value or the like illustrated in the drawings.

Herein, “first”, “second”, “third” and other ordinal numerals are configured to avoid the confusion of the constituent elements, rather than to limit the quantity. Herein, “a plurality of” denotes the number of two or more than two.

Herein, for convenience, phrases such as “middle”, “up”, “down”, “front”, “back”, “vertical”, “horizontal”, “top”, “bottom”, “inside”, and “outside” indicating the orientation or position relationship are used to describe the position relationship of the constituent elements with reference to the drawings, only for the convenience of describing the embodiments and simplifying the description, instead of indicating or implying that the device or element referred to necessarily has a specific orientation or is constructed and operated in a specific orientation, so they should not be construed as limitations to the present disclosure. The position relationship of the constituent elements may be appropriately changed according to the direction of the described constituent elements. Therefore, the phrases described herein are not restrictive, and may be appropriately replaced according to the situation.

Herein, unless otherwise specified and limited, the terms “mount”, “couple”, and “connect” should be understood in a broad sense. For example, it may be a fixed connection, a detachable connection, or an integrated connection, may be a mechanical connection or an electrical connection, or may be a direct connection, an indirect connection performed via an intermediate component, or communication of the interiors of two components. For those skilled in the art, the meanings of the above terms in the present disclosure can be understood according to the situation.

Herein, a transistor refers to a component which includes at least three terminals, i.e., a gate electrode, a drain electrode, and a source electrode. The transistor has a channel region between the drain electrode (or referred as drain electrode terminal, drain region, or drain electrode) and the source electrode (or referred as source electrode terminal, source region, or source electrode), and the current can flow through the drain electrode, the channel region, and the source electrode. Herein, the channel region refers to a region where the current mainly flows.

Herein, a first electrode may be a drain electrode and a second electrode may be a source electrode, or a first electrode may be a source electrode and a second electrode may be a drain electrode. The functions of “source electrode” and “drain electrode” may sometimes be exchanged when transistors of opposite polarities are used or when the current direction changes during circuit operation. Therefore, “source electrode” and “drain electrode” herein may be exchanged.

Herein, “electrical connection” includes the case where constituent elements are connected together by a component having a certain electrical action. As long as electrical signals between the connected constituent elements can be received, there is no special limitation to “component having a certain electrical action”. “Component having a certain electrical action”, for example, may be an electrode or wiring, or a switching element such as a transistor, or other functional element such as a resistor, an inductor, or a capacitor.

Herein, “parallel” refers to a state in which an angle formed by two straight lines is greater than −10° and less than 10°. Therefore, it also includes a state in which an angle is greater than −5° and less than 5°. In addition, “vertical” refers to a state in which an angle formed by two straight lines is greater than 80° and less than 100°. Therefore, it also includes a state in which an angle is greater than 85° and less than 95°.

Herein, “film” and “layer” may be exchanged. For example, sometimes “conducting layer” may be replaced by “conducting film”. Similarly, sometimes “insulating film” may be replaced by “insulating layer”.

Herein, “about” refers to a numerical value within a range of allowable process and measurement errors without strictly limiting the limit.

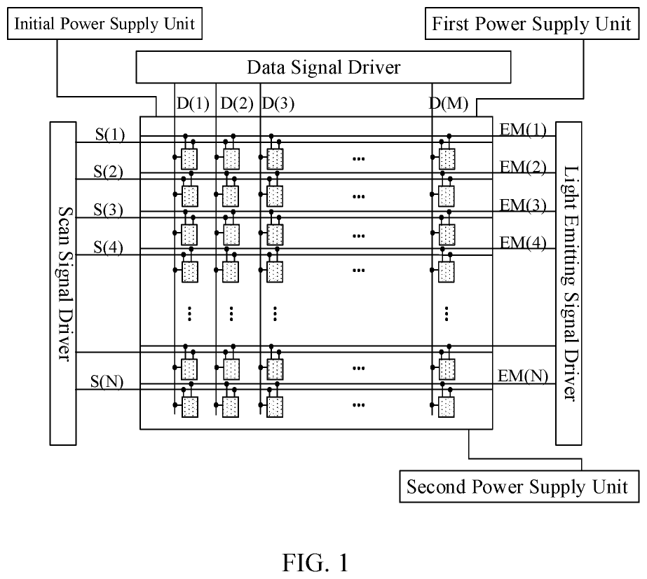

FIG. 1 is a schematic diagram of a structure of a display device. Referring to FIG. 1, the display device may include: a scan signal driver, a data signal driver, a light emitting signal driver, a display base plate, a first power supply unit, a second power supply unit, and an initial power supply unit. In some exemplary embodiments, the display base plate at least includes a plurality of scan signal wires (S(1) to S(N)), a plurality of data signal wires (D(1) to D(M)), and a plurality of light emitting signal wires (EM(1) to EM(N)). The scan signal driver is configured to sequentially provide scan signals to the plurality of scan signal wires (S(1) to S(N)), the data signal driver is configured to sequentially provide data signals to the plurality of data signal wires (D(1) to D(M)), and the light emitting signal driver is configured to sequentially provide light emitting control signals to the plurality of light emitting signal wires (EM(1) to EM(N)). In some exemplary embodiments, the plurality of scan signal wires and the plurality of light emitting signal wires extend along the horizontal direction, and the plurality of data signal wires extend in the vertical direction. The display base plate includes a plurality of sub-pixels, and each sub-pixel includes a pixel drive circuit and a light emitting device. The pixel drive circuit is connected to the scan signal wire, the light emitting control line, and the data signal wire, and the pixel drive circuit is configured to receive a data voltage transmitted by the data signal wire and output a corresponding current to the light emitting device under the control of the scan signal wire and the light emitting signal wire. The light emitting device is connected to the pixel drive circuit, and the light emitting device is configured to emit light of corresponding brightness in response to the current output by the pixel drive circuit. The first power supply unit, the second power supply unit, and the initial power supply unit are respectively configured to provide a first power supply voltage, a second power supply voltage, and an initial power supply voltage to the pixel drive circuit via a first power supply line, a second power supply line, and an initial signal wire.

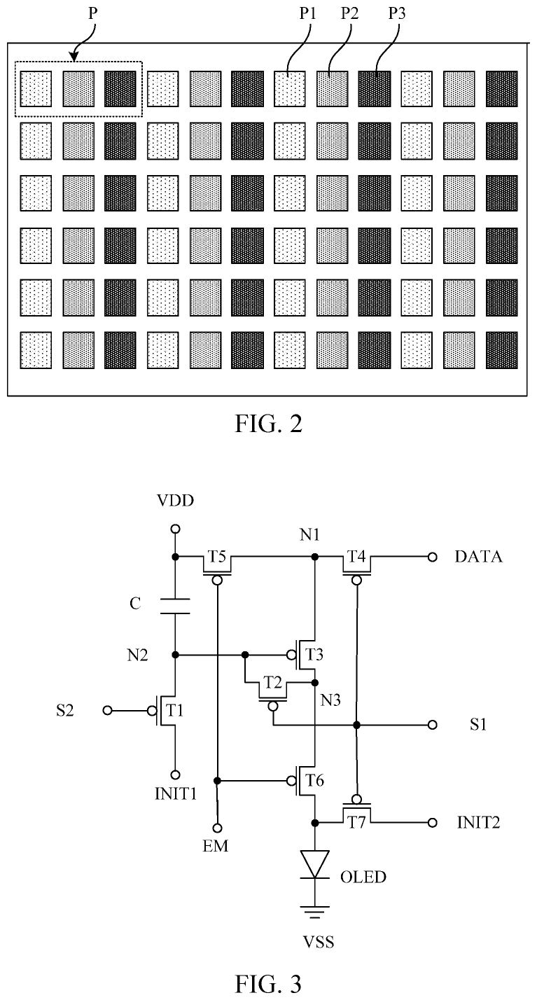

FIG. 2 is a schematic diagram of a planar structure of the display base plate. Referring to FIG. 2, a display region may include a plurality of pixel units P arranged in an array. At least one of the plurality of pixel units P includes a first sub-pixel P1 emitting first-color light, a second sub-pixel P2 emitting second-color light, and a third sub-pixel P3 emitting third-color light. The first sub-pixel P1, the second sub-pixel P2, and the third sub-pixel P3 each include a pixel drive circuit and a light emitting device. In some exemplary embodiments, the pixel unit P may include a red (R) sub-pixel, a green (G) sub-pixel, and a blue (B) sub-pixel, or may include a red sub-pixel, a green sub-pixel, a blue sub-pixel, and a white (W) sub-pixel, which is not limited in the present disclosure. In some exemplary embodiments, the shape of the sub-pixel in the pixel unit may be a rectangle, a rhombus, a pentagon, or a hexagon. When the pixel unit includes three sub-pixels, the three sub-pixels may be arranged in parallel horizontally, in parallel vertically, or in a regular triangle shape. When the pixel unit includes four sub-pixels, the four sub-pixels may be arranged in parallel horizontally, in parallel vertically, or a square shape. However, the present disclosure is not limited thereto.

In some exemplary embodiments, the pixel drive circuit may be a 3T1C, 4T1C, 5T1C, 5T2C, 6T1C, or 7T1C structure. FIG. 3 is an equivalent circuit diagram of the pixel drive circuit. Referring to FIG. 3, the pixel drive circuit may include seven switching transistors (first transistor T1 to seventh transistor T7), one storage capacitor C, and eight signal wires (i.e., a data signal wire DATA, a first scan signal wire S1, a second scan signal wire S2, a first initial signal wire INIT1, a second initial signal wire INIT2, a first power supply line VSS, a second power supply line VDD, and a light emitting signal wire EM). The first initial signal wire INIT1 and the second initial signal wire INIT2 may be the same signal wire.

In some exemplary embodiments, a control electrode of the first transistor T1 is connected to the second scan signal wire S2, a first electrode of the first transistor T1 is connected to the first initial signal wire INIT1, and a second electrode of the first transistor T1 is connected to a second node N2. A control electrode of the second transistor T2 is connected to the first scan signal wire S1, a first electrode of the second transistor T2 is connected to the second node N2, and a second electrode of the second transistor T2 is connected to a third node N3. A control electrode of the third transistor T3 is connected to the second node N2, a first electrode of the third transistor T3 is connected to a first node N1, and a second electrode of the third transistor T3 is connected to the third node N3. A control electrode of the fourth transistor T4 is connected to the first scan signal wire S1, a first electrode of the fourth transistor T4 is connected to the data signal wire DATA, and a second electrode of the fourth transistor T4 is connected to the first node N1. A control electrode of the fifth transistor T5 is connected to the light emitting signal wire EM, a first electrode of the fifth transistor T5 is connected to the second power supply line VDD, and a second electrode of the fifth transistor T5 is connected to the first node N1. A control electrode of the sixth transistor T6 is connected to the light emitting signal wire EM, a first electrode of the sixth transistor T6 is connected to the third node N3, and a second electrode of the sixth transistor T6 is connected to a first electrode of the light emitting device. A control electrode of the seventh transistor T7 is connected to the first scan signal wire S1, a first electrode of the seventh transistor T7 is connected to the second initial signal wire INIT2, and a second electrode of the seventh transistor T7 is connected to the first electrode of the light emitting device. A first end of the storage capacitor C is connected to the second power supply line VDD, and a second end of the storage capacitor C is connected to the second node N2.

In some exemplary embodiments, the first transistor T1 to the seventh transistor T7 may be P-type transistors or may be N-type transistors. The use of the same type of transistors in the pixel drive circuit can simplify the process flow, reduce the process difficulty of a display panel, and improve the yield of a product. In some possible embodiments, the first transistor T1 to the seventh transistor T7 may include P-type transistors and N-type transistors.

In some exemplary embodiments, a second electrode of the light emitting device is connected to the first power supply line VSS. A signal of the first power supply line VSS is a low-level signal and a signal of the second power supply line VDD is a high-level signal. The first scan signal wire S1 is a scan signal wire in the pixel drive circuit of a current display line, and the second scan signal wire S2 is a scan signal wire in the pixel drive circuit of a previous display line, that is, for the n-th display line, the first scan signal wire S1 is S(n) and the second scan signal wire S2 is S(n−1). The second scan signal wire S2 of the current display line and the first scan signal wire S1 of the pixel drive circuit of the previous display line are the same signal wire, thus reducing the number of the signal wires of the display panel and realizing a narrow frame of the display panel.

FIG. 4 is a schematic diagram of a sectional structure of the display base plate, illustrating a structure of three sub-pixels of the display base plate. Referring to FIG. 4, on a plane perpendicular to the display base plate, the display base plate may include a drive circuit layer 102 disposed on a substrate 101, a light emitting device 103 disposed on a side of the drive circuit layer 102 away from the substrate 101, and a packaging layer 104 disposed on a side of the light emitting device 103 away from the substrate 101. In some possible embodiments, the display base plate may include other film layers, such as a column spacer, which is not limited in the present disclosure.

In some exemplary embodiments, the substrate 101 may be a flexible substrate or may be a rigid substrate. The flexible substrate may include a first flexible material layer, a first inorganic material layer, a semiconductor layer, a second flexible material layer, and a second inorganic material layer. The materials of the first flexible material layer and the second flexible material layer may be polyimide (PI), polyethylene terephthalate (PET), a polymer soft film subjected to surface treatment, or the like. The materials of the first inorganic material layer and the second inorganic material layer may be silicon nitride (SiNx), silicon oxide (SiOx), or the like, so as to improve the water-oxygen resistance of the substrate. The material of the semiconductor layer may be amorphous silicon (a-si).

In some exemplary embodiments, the drive circuit layer 102 of each sub-pixel may include a plurality of transistors and a storage capacitor forming the pixel drive circuit. In FIG. 4, illustration is performed by taking each sub-pixel including a drive transistor and a storage capacitor as an example. In some possible embodiments, the drive circuit layer 102 of each sub-pixel may include: a first insulating layer 201 disposed on the substrate; an active layer disposed on the first insulating layer; a second insulating layer 202 covering the active layer; a gate electrode and a first capacitor electrode disposed on the second insulating layer 202; a third insulating layer 203 covering the gate electrode and the first capacitor electrode; a second capacitor electrode disposed on the third insulating layer 203; a fourth insulating layer 204 covering the second capacitor electrode, the second insulating layer 202, the third insulating layer 203, and the fourth insulating layer 204 being provided with vias, the vias exposing the active layer; a source electrode and a drain electrode disposed on the fourth insulating layer 204, the source electrode and the drain electrode being separately connected to the active layer by means of the vias; and a planarization layer 205 covering the structure described above, the planarization layer 205 being provided with a via, the via exposing the drain electrode. The active layer, the gate electrode, the source electrode, and the drain electrode form a drive transistor 210. The first capacitor electrode and the second capacitor electrode form a storage capacitor 211.

In some exemplary embodiments, the light emitting device 103 may include an anode 301, a pixel definition layer 302, an organic light emitting layer 303, and a cathode 304. The anode 301 is disposed on the planarization layer 205, and is connected to the drain electrode of the drive transistor 210 by means of the via provided in the planarization layer 205. The pixel definition layer 302 is disposed on the anode 301 and the planarization layer 205, and the pixel definition layer 302 is provided with a pixel opening, the pixel opening exposing the anode 301. The organic light emitting layer 303 is at least partially disposed in the pixel opening, and the organic light emitting layer 303 is connected to the anode 301. The cathode 304 is disposed on the organic light emitting layer 303, and the cathode 304 is connected to the organic light emitting layer 303. The organic light emitting layer 303 emits light of a corresponding color under the drive of the anode 301 and the cathode 304.

In some exemplary embodiments, the packaging layer 104 may include a first packaging layer 401, a second packaging layer 402, and a third packaging layer 403 that are stacked. The first packaging layer 401 and the third packaging layer 403 may be made of an inorganic material, the second packaging layer 402 may be made of an organic material, and the second packaging layer 402 is disposed between the first packaging layer 401 and the third packaging layer 403 to ensure that external water vapor cannot enter the light emitting device 103.

In some exemplary embodiments, the organic light emitting layer of the light emitting device may include an emitting layer (EML), and includes one or more film layers selected from a hole injection layer (HIL), a hole transport layer (HTL), a hole blocking layer (HBL), an electron blocking layer (EBL), an electron injection layer (EIL), and an electron transporting layer (ETL). Under the drive of the voltage of the anode and the cathode, light is emitted at a required gray tone by means of a light emitting property of the organic material.

In some exemplary embodiments, emitting layers of OLED light emitting devices of different colors are different. For example, a red light emitting device includes a red light emitting layer, a green light emitting device includes a green light emitting layer, and a blue light emitting device includes a blue light emitting layer. In order to reduce the difficulty of the process and improve the yield, the hole injection layer and hole transport layer on one side of the emitting layer may adopt a connecting layer, and the electron injection layer and the electron transporting layer on the other side of the emitting layer may adopt a connecting layer. In some exemplary embodiments, any one or more of the hole injection layer, the hole transport layer, the electron injection layer, and the electron transporting layer may be produced by a one-time process (one-time evaporation process or one-time inkjet printing process), which, however, are isolated from each other by means of a surface segment difference between the formed film layers or surface treatment. For example, any one or more of hole injection layers, hole transport layers, electron injection layers, and electron transporting layers corresponding to adjacent sub-pixels may be isolated from each other. In some exemplary embodiments, the organic light emitting layer may be prepared by means of evaporation using a Fine Metal Mask (FMM) or an open mask or by means of an inkjet process.

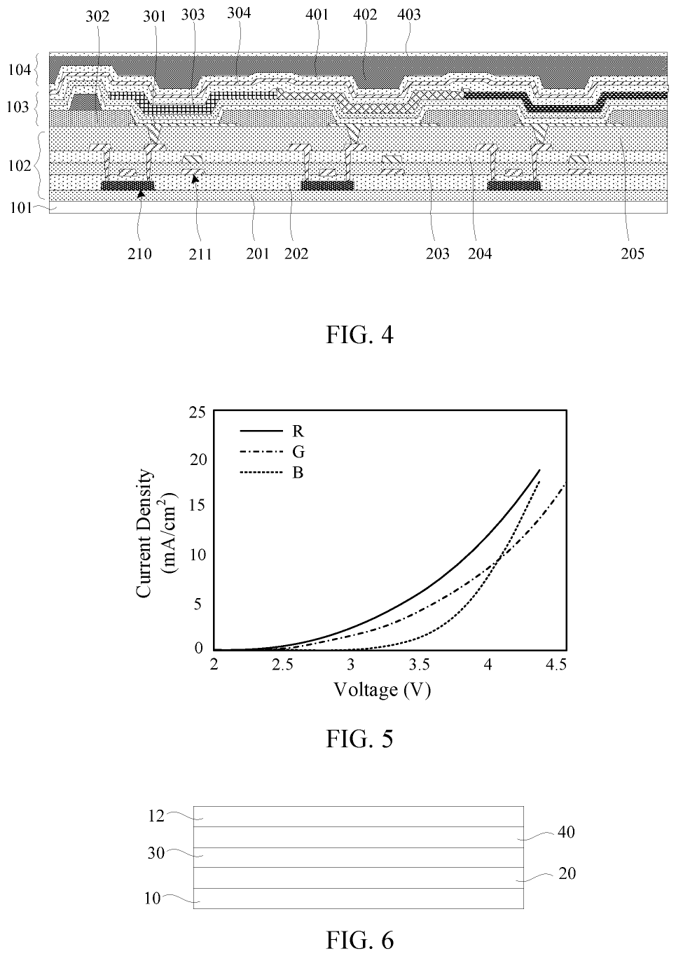

In a display base plate, light emitting devices of different colors have the same film layer structure, and different amounts of energy are required to excite the light emitting materials in the emitting layers of the light emitting devices of different colors to emit light of different colors. Taking the red light emitting device, the green light emitting device, and the blue light emitting device as an example, the order of the amounts of energy required by the emitting layers of these three light emitting devices to emit corresponding red (R) light, green (G) light, and blue (B) light is as follows: vR<vG<vB. Therefore, at a low gray tone, the red light emitting device emits light first, while the green light emitting device and the blue light emitting device cannot emit light because it does not reach the energy required to emit light, leading to a low gray tone redness phenomenon of the display device. FIG. 5 is a curve graph of voltage-current densities of light emitting devices of RGB three colors. Referring to FIG. 5, a startup voltage of the blue light emitting device is greater than a startup voltage of the green light emitting device and is greater than a startup voltage of the red light emitting device; and the startup voltage of the green light emitting device is greater than the startup voltage of the red light emitting device. In some examples, when the hole injection layers of the light emitting devices of RGB three colors adopt a connecting layer, and when the blue light emitting device is switched on at a light emitting stage, since the conductive performance of the hole injection layer used as the connecting layer is relatively well, a part of the voltage is applied to the red light emitting device or green light emitting device via the common hole injection layer. Since the startup voltages of the red light emitting device and green light emitting device both are less than the startup voltage of the blue light emitting device, the red light emitting device and the green light emitting device are easy to be switched on. Therefore, the red light emitting device and the green light emitting device cannot achieve a low-brightness display effect at the low gray tone in strict accordance with the requirement, and a low gray tone color cast phenomenon thus is apt to occur.

Moreover, with the continuous development of products, the market requires increasingly higher display resolution and increasingly lower power consumption of products, that is, the absolute value of the voltage VSS is constantly reduced, which means that a difference between voltages applied to two ends of the light emitting device at the light emitting stage is constantly decreasing. At the low gray tone, when the difference between voltages applied the two ends of the light emitting device is less than the startup voltage of the green light emitting device, the display redness phenomenon is more apt to occur.

FIG. 6 is a schematic diagram of a structure of an OLED provided by at least one embodiment of the present disclosure. Referring to FIG. 6, the OLED provided by this embodiment includes: a first electrode 10, a second electrode 12, and an organic light emitting layer disposed between the first electrode 10 and the second electrode 12. In some exemplary embodiments, the first electrode 10 is an anode and the second electrode 12 is a cathode. The organic light emitting layer includes a hole transport layer 20, an electron blocking layer 30, and an emitting layer 40 that are stacked. The hole transport layer 20 is disposed between the first electrode 10 and the electron blocking layer 30, and the electron blocking layer 30 is disposed between the hole transport layer 20 and the emitting layer 40. In some examples, the hole transport layer 20 is configured to achieve directional and orderly controlled migration of injected holes. The hole mobility of the electron blocking layer 30 is greater than the electromigration, and the electron blocking layer 30 is configured to form a migration barrier for electrons to prevent the electrons from migrating out of the emitting layer 40. The emitting layer 40 is configured to combine the electrons and holes to emit light.

In some exemplary embodiments, the material of the electron blocking layer includes a compound having the following structural formula:

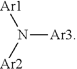

Ar1 to Ar3 are separately one of a substituted or unsubstituted aryl group with 6 to 40 carbon atoms, a substituted or unsubstituted heteroaryl group with 3 to 40 carbon atoms, a substituted or unsubstituted alkyl group with 1 to 20 carbon atoms, and a substituted or unsubstituted cycloalkyl group with 1 to 30 carbon atoms.

At least one of Ar1 to Ar3 is connected to the following structure:

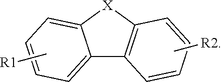

X is one of carbon (C), nitrogen (N), sulfur (S), and oxygen (O).

R1 and R2 are separately one of hydrogen, deuterium, an alkyl group with 1 to 30 carbon atoms, a substituted or unsubstituted cycloalkyl group with 3 to 40 carbon atoms, a substituted or unsubstituted alkenyl group with 2 to 30 carbon atoms, a substituted or unsubstituted alkynyl group with 2 to 30 carbon atoms, a substituted or unsubstituted heteroalkyl group with 2 to 30 carbon atoms, a substituted or unsubstituted arylalkyl group with 7 to 30 carbon atoms, a substituted or unsubstituted aryl group with 6 to 30 carbon atoms, and a substituted or unsubstituted heteroaryl group with 2 to 30 carbon atoms.

In some exemplary embodiments, Ar1, Ar2, and Ar3 are at least partially the same or different from each other, and R1 and R2 are the same or different. For example, Ar1 to Ar3 are the same, or two of Ar1 to Ar3 are the same, or Ar1 to Ar3 are different from each other. However, this embodiment is not limited thereto.

In some exemplary embodiment, the material of the hole transport layer includes a compound having the following structural formula:

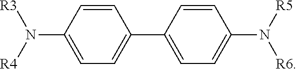

R3 to R6 are separately one of deuterium, a cyano group, a nitro group, halogen, a hydroxyl group, a substituted or unsubstituted alkyl group with 1 to 30 carbon atoms, a substituted or unsubstituted cycloalkyl group with 1 to 20 carbon atoms, a substituted or unsubstituted alkenyl group with 2 to 30 carbon atoms, a substituted or unsubstituted alkynyl with 2 to 24 carbon atoms, a substituted or unsubstituted heteroalkyl group with 2 to 30 carbon atoms, a substituted or unsubstituted arylalkyl group with 7 to 30 carbon atoms, a substituted or unsubstituted aryl group with 6 to 30 carbon atoms, a substituted or unsubstituted heteroaryl group with 2 to 30 carbon atoms, a substituted or unsubstituted heteroaryl group with 3 to 30 carbon atoms, a substituted or unsubstituted alkoxy group with 1 to 30 carbon atoms, a substituted or unsubstituted alkylamino group with 1 to 30 carbon atoms, a substituted or unsubstituted arylamino group with 6 to 30 carbon atoms, a substituted or unsubstituted arylalkylamino group with 6 to 30 carbon atoms, a substituted or unsubstituted heteroarylamino group with 2 to 24 carbon atoms, a substituted or unsubstituted alkylmethylsilyl group with 1 to 30 carbon atoms, a substituted or unsubstituted arylmethylsilyl group with 6 to 30 carbon atoms, and a substituted or unsubstituted aryloxy group with 6 to 30 carbon atoms.

In the OLED provided by this exemplary embodiment, a difference between energy levels of the hole transport layer and the electron blocking layer is adjusted by selecting a combination of the materials of the hole transport layer and the electron blocking layer, so as to realize the adjustment of a startup voltage of the OLED.

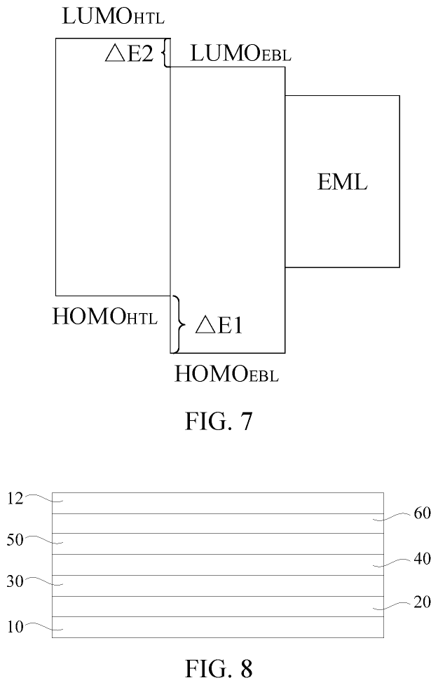

FIG. 7 is a schematic diagram of an energy level relationship of the OLED according to at least one embodiment of the present disclosure. Referring to FIG. 7, the Highest Occupied Molecular Orbital (HOMO) energy level HOMOEBL of the electron blocking layer (EBL) is higher than the HOMO energy level HOMOHTL of the hole transport layer (HTL). In some exemplary embodiments, the electron blocking layer and the hole transport layer satisfy the following condition:

0.3 eV≤|HOMO_{EBL}|−|HOMO_{HTL}|≤0.7 eV, i.e., 0.3 eV≤ΔE1≤0.7 eV.

In this exemplary embodiment, by combining the materials of the hole transport layer and the electron blocking layer, a difference between the HOMO energy levels of the electron blocking layer and the hole transport layer can be increased, thus increasing energy required for hole transport and improving the startup voltage of the OLED.

In some exemplary embodiments, the HOMO energy level of the electron blocking layer is about −5.4 eV to −6.2 eV, and the HOMO energy level of the hole transport layer is about −5.3 eV to −5.6 eV.

In some exemplary embodiments, referring to FIG. 7, the Lowest Unoccupied Molecular Orbital (LUMO) energy level LUMO_{EBL} of the electron blocking layer (EBL) is lower than the LUMO energy level LUMO_{HTL} of the hole transport layer (HTL). In some examples, the electron blocking layer and the hole transport layer further satisfy the following condition:

0.3 eV≤LUMO_{HTL}−LUMO_{EBL}≤0.8 eV, i.e., 0.3 eV≤ΔE2≤0.8 eV

In some exemplary embodiments, the LUMO energy level of the electron blocking layer is about −2.2 eV to −2.4 eV, and the LUMO energy level of the hole transport layer is about −2.2 eV to −2.5 eV.

In some exemplary embodiments, the electron blocking layer may have a thickness of about 3 nm to 10 nm.

In some exemplary embodiments, the HOMO energy level and LUMO energy level may be measured by means of a photoelectron spectrophotometer (AC3/AC2) or ultraviolet (UV) spectroscopy.

In some exemplary embodiments, the emitting layer may be a red light emitting layer. In this exemplary embodiment, by increasing the startup voltage of the red OLED, a difference between the startup voltages of the OLEDs of different colors in the display device can be effectively adjusted, thus improving the low gray tone color cast phenomenon and improving the display effect.

In some exemplary embodiments, the hole transport layer may include but is not limited to compounds having structures represented by formula 1-1 to formula 1-9:

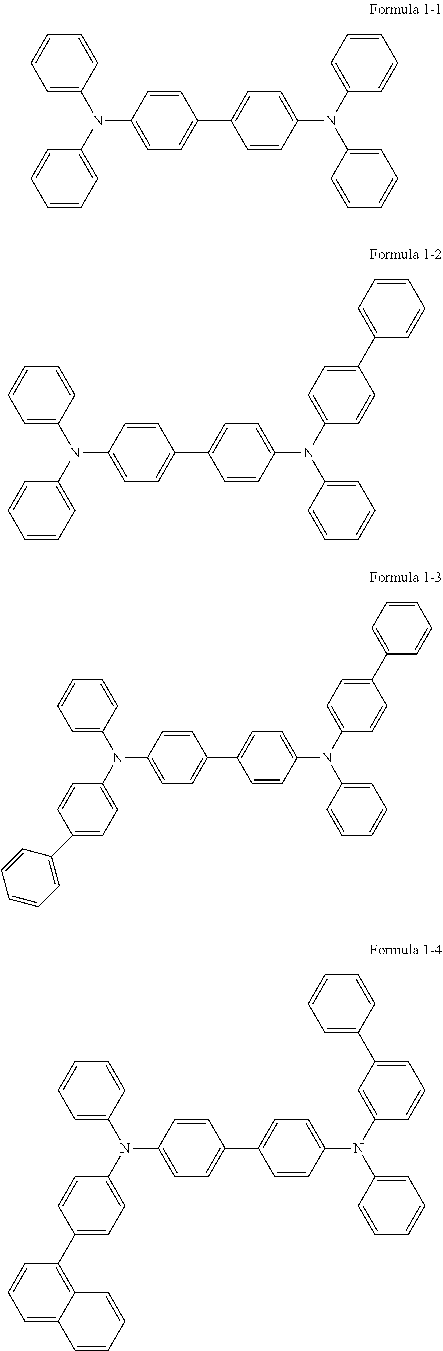 [SMILES: c1ccc(N(c2ccccc2)c2ccc(-c3ccc(N(c4ccccc4)c4ccccc4)cc3)cc2)cc1 ; c1ccc(-c2ccc(N(c3ccccc3)c3ccc(-c4ccc(N(c5ccccc5)c5ccccc5)cc4)cc3)cc2)cc1 ; c1ccc(-c2ccc(N(c3ccccc3)c3ccc(-c4ccc(N(c5ccccc5)c5ccc(-c6ccccc6)cc5)cc4)cc3)cc2)cc1 ; c1ccc(-c2cccc(N(c3ccccc3)c3ccc(-c4ccc(N(c5ccccc5)c5ccc(-c6cccc7ccccc67)cc5)cc4)cc3)c2)cc1]

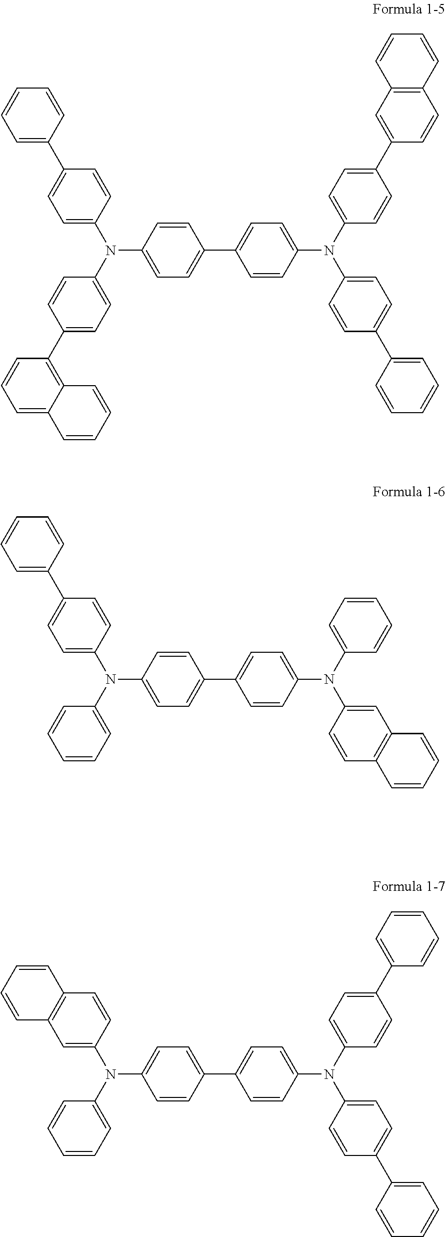 [SMILES: c1ccc(-c2ccc(N(c3ccc(-c4ccc(N(c5ccc(-c6ccccc6)cc5)c5ccc(-c6cccc7ccccc67)cc5)cc4)cc3)c3ccc(-c4ccc5ccccc5c4)cc3)cc2)cc1 ; c1ccc(-c2ccc(N(c3ccccc3)c3ccc(-c4ccc(N(c5ccccc5)c5ccc6ccccc6c5)cc4)cc3)cc2)cc1 ; c1ccc(-c2ccc(N(c3ccc(-c4ccccc4)cc3)c3ccc(-c4ccc(N(c5ccccc5)c5ccc6ccccc6c5)cc4)cc3)cc2)cc1]

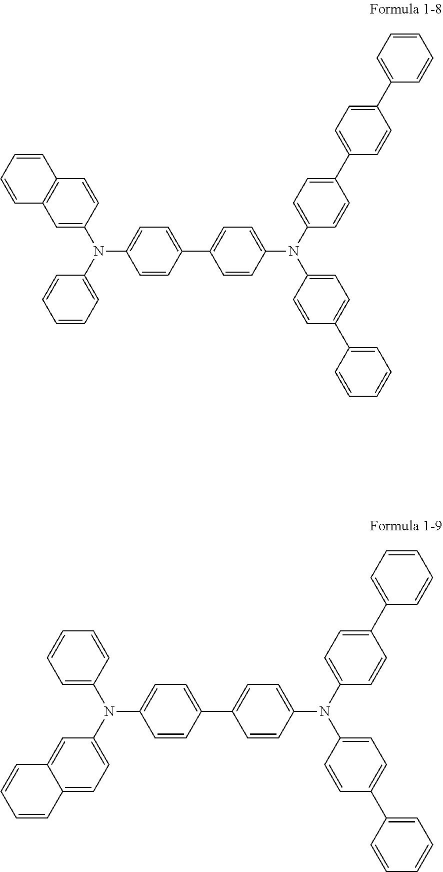 [SMILES: c1ccc(-c2ccc(-c3ccc(N(c4ccc(-c5ccccc5)cc4)c4ccc(-c5ccc(N(c6ccccc6)c6ccc7ccccc7c6)cc5)cc4)cc3)cc2)cc1 ; c1ccc(-c2ccc(N(c3ccc(-c4ccccc4)cc3)c3ccc(-c4ccc(N(c5ccccc5)c5ccc6ccccc6c5)cc4)cc3)cc2)cc1]

In some exemplary embodiments, the electron blocking layer may include but is not limited to compounds having structures represented by formula 2-1 to formula 2-9:

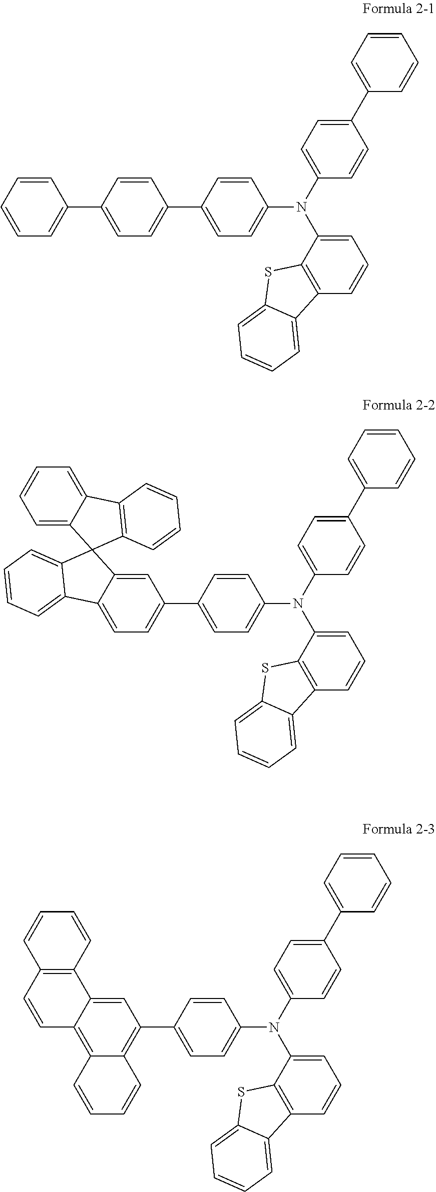 [SMILES: c1ccc(-c2ccc(-c3ccc(N(c4ccc(-c5ccccc5)cc4)c4cccc5c4sc4ccccc45)cc3)cc2)cc1 ; c1ccc(-c2ccc(N(c3ccc(-c4ccc5c(c4)C4(c6ccccc6-c6ccccc64)c4ccccc4-5)cc3)c3cccc4c3sc3ccccc34)cc2)cc1 ; c1ccc(-c2ccc(N(c3ccc(-c4cc5c6ccccc6ccc5c5ccccc45)cc3)c3cccc4c3sc3ccccc34)cc2)cc1]

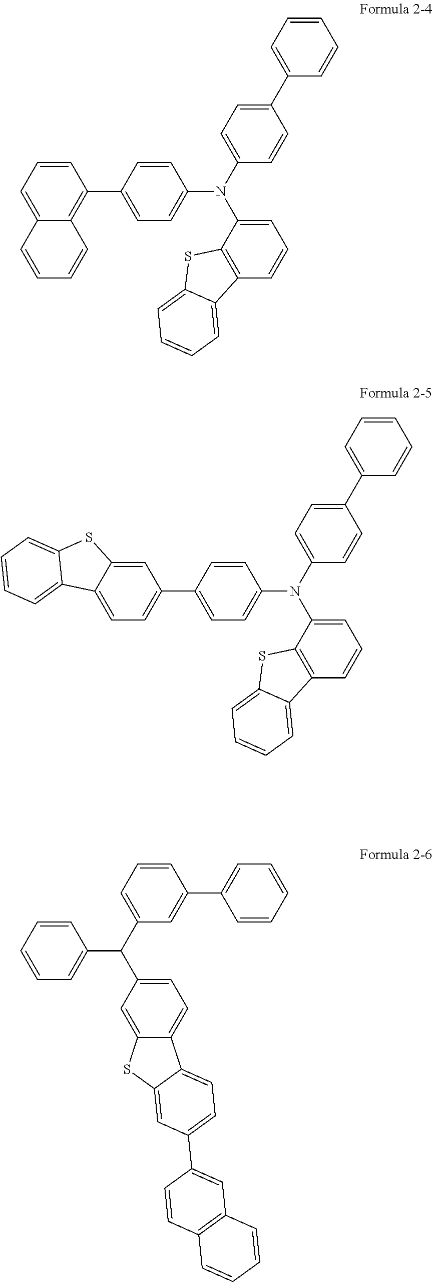 [SMILES: c1ccc(-c2ccc(N(c3ccc(-c4cccc5ccccc45)cc3)c3cccc4c3sc3ccccc34)cc2)cc1 ; c1ccc(-c2ccc(N(c3ccc(-c4ccc5c(c4)sc4ccccc45)cc3)c3cccc4c3sc3ccccc34)cc2)cc1 ; c1ccc(-c2cccc(C(c3ccccc3)c3ccc4c(c3)sc3cc(-c5ccc6ccccc6c5)ccc34)c2)cc1]

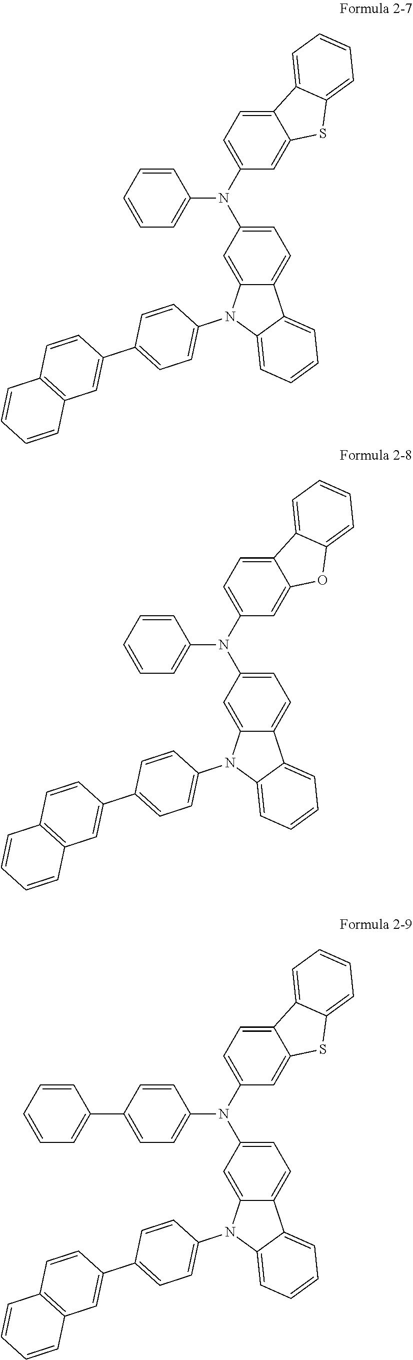 [SMILES: c1ccc(N(c2ccc3c(c2)sc2ccccc23)c2ccc3c4ccccc4n(-c4ccc(-c5ccc6ccccc6c5)cc4)c3c2)cc1 ; c1ccc(N(c2ccc3c(c2)oc2ccccc23)c2ccc3c4ccccc4n(-c4ccc(-c5ccc6ccccc6c5)cc4)c3c2)cc1 ; c1ccc(-c2ccc(N(c3ccc4c(c3)sc3ccccc34)c3ccc4c5ccccc5n(-c5ccc(-c6ccc7ccccc7c6)cc5)c4c3)cc2)cc1]

In some exemplary embodiments, the electron blocking layer and the hole transport layer may be other materials that satisfy the above structural formulas and energy level relationships known by those skilled in the art. However, this embodiment is not limited thereto.

FIG. 8 is a schematic diagram of a structure of another OLED according to at least one embodiment of the present disclosure. Referring to FIG. 8, the OLED in this exemplary embodiment includes: a first electrode 11, a second electrode 12, and an organic light emitting layer disposed between the first electrode 11 and the second electrode 12. In some exemplary embodiments, the first electrode 11 is an anode and the second electrode 12 is a cathode. The organic light emitting layer includes a hole transport layer 20, an electron blocking layer 30, an emitting layer 40, a hole blocking layer 50, and an electron transporting layer 60 that are stacked. The hole transport layer 20 and the electron blocking layer 30 are disposed between the first electrode 10 and the emitting layer 40, the hole transport layer 20 is connected to the first electrode 10, the electron blocking layer 30 is connected to the emitting layer 40, and the electron blocking layer 30 is located between the hole transport layer 20 and the emitting layer 40. The hole blocking layer 50 and the electron transporting layer 60 are disposed between the emitting layer 40 and the second electrode 12, the hole blocking layer 50 is connected to the emitting layer 40, the electron transporting layer 60 is connected to the second electrode 12, and the hole blocking layer 50 is located between the emitting layer 40 and the electron transporting layer 60. However, this embodiment is not limited thereto. In some examples, a hole injection layer may be disposed between the hole transport layer and the first electrode, and an electron injection layer may be disposed between the electron transporting layer and the second electrode. The hole injection layer can reduce the barrier of injecting holes from the first electrode, such that the holes can be effectively injected into the emitting layer from the first electrode. The electron injection layer can reduce the barrier of injecting electrons from the second electrode, such that the electrons can be effectively injected into the emitting layer from the second electrode.

In some exemplary embodiments, the hole transport layer 20 is configured to achieve directional and orderly controlled migration of injected holes. The hole mobility of the electron blocking layer 30 is greater than the electromigration, and the electron blocking layer 30 may be configured to form a migration barrier for electrons to prevent the electrons from migrating out of the emitting layer 40. The emitting layer 40 is configured to combine the electrons and holes to emit light. The hole blocking layer 50 is configured to form a migration barrier for holes to prevent the holes from migrating out of the emitting layer 40. The electron transporting layer 60 is configured to achieve directional and orderly controlled migration of injected electrons.

In some exemplary embodiments, the anode may be made of a material with a high work function. For a bottom emission type, the anode may be made of a transparent oxide material such as indium tin oxide (ITO) or indium zinc oxide (IZO), and the anode may have a thickness of about 80 nm to 200 nm. For a top emitting type, the anode may be made of a compound structure of metal and transparent oxide, such as AG/ITO, Ag/IZO, or ITO/Ag/ITO, a metal layer in the anode may have a thickness of about 80 nm to 100 nm, and the transparent oxide in the anode may have a thickness of about 5 nm to 20 nm, such that the average reflectivity of the anode regarding a visible light range is about 85% to 95%.

In some exemplary embodiments, for a top emitting type OLED, the cathode may be made of a metal material and be formed by means of an evaporation process, the metal material may be magnesium (Mg), silver (Ag), or aluminum (Al), or an alloy material, such as Mg:Ag alloy, with the Mg:Ag ratio of about 9:1 to 1:9, and the cathode may have a thickness of about 10 nm to 20 nm, such that the average transmittance of the cathode regarding a wavelength of 530 nm is about 50% to 60%. For a bottom emission type OLED, the cathode may be made of magnesium (Mg), silver (Ag), aluminum (Al), or Mg:Ag alloy, the cathode may have a thickness of about more than 80 nm, and for example, the cathode may have a thickness of about 150 nm, such that the cathode has good reflectivity.

In some exemplary embodiments, the hole injection layer may be made of inorganic oxide such as molybdenum oxide, titanium oxide, vanadium oxide, rhenium oxide, ruthenium oxide, chromium oxide, zirconium oxide, hafnium oxide, tantalum oxide, silver oxide, tungsten oxide, or manganese oxide, or may be made of a p-type doping agent of a strong electron-withdrawing system and a dopant of a hole transport material, such as hexacyanohexaazatriphenylene, 2,3,5,6-tetrafluoro-7,7′, 8, 8′-tetracyanoquinodimethane (F4-TCNQ), or 1,2,3-tri[(cyano)(4-cyano-2,3,5,6-tetrafluorophenyl)methylene]cyclopropane. In some examples, the hole injection layer may have a thickness of about 5 nm to 20 nm.

In some exemplary embodiments, for the materials of the hole transport layer and the electron blocking layer, a reference may be made to the description of the above embodiments, which are thus not described again herein.

In some exemplary embodiments, the hole transport layer may have a thickness of about 80 nm to 120 nm. The conductivity of the hole transport layer may be less than or equal to the conductivity of the hole injection layer.

In some exemplary embodiments, the hole blocking layer is made of a condensed nitrogen heterocyclic derivative, such as 2, 9-dimethyl-4,7-biphenyl-1,10-phenanthroline, 1,3,5-tris(1-phenyl-1H-benzimidazol-2-yl)b enzene, or bathocuproine (BCP). In some exemplary embodiments, the hole blocking layer may have a thickness of about 1 nm to 15 nm.

In some exemplary embodiments, the electron transporting layer may be made of a material such as a condensed nitrogen heterocyclic derivative or a metal complex compound, for example, any one of 2-(4-biphenyl)-5-phenyloxadiazole (PBD), 2,5-bis(1-naphthyl)-1,3,5-oxadiazole (BND), and 2,4,6-triphenoxy-1,3,5-triazine (TRZ). In some exemplary embodiments, the electron transporting layer may have a thickness of about 10 nm to 30 nm.

In some exemplary embodiments, the electron injection layer may be made of alkali metal or metal, such as lithium fluoride (LiF), ytterbium (Yb), magnesium (Mg), or calcium (Ca), or compounds of the alkali metal or metal. In some exemplary embodiments, the electron injection layer may have a thickness of about 0.5 nm to 2 nm.

In some exemplary embodiments, the OLED may include a packaging layer, and the packaging layer may adopt a cover plate or a thin film for encapsulation.

In some exemplary embodiments, for the top emitting type OLED, the thickness of the organic light emitting layer between the cathode and the anode may be designed according to the requirement of an optical path satisfying an optical micro resonant cavity, so as to obtain optimal light intensity and color.

In some exemplary embodiments, a display base plate including the OLED as illustrated in FIG. 8 may be prepared by means of the following preparation method.

First, a drive circuit layer is formed on a substrate by means of a patterning process, wherein each drive circuit layer of each sub-pixel may include a drive transistor and a storage capacitor which form the pixel drive circuit. Then, a planarization layer is formed on the substrate on which the above structure is formed. A via exposing a drain electrode of the drive transistor is formed in the planarization layer of each sub-pixel. Then, an anode is formed by means of a patterning process on the substrate on which the above structure is formed, wherein the anode of each sub-pixel is connected to the drain electrode of the drive transistor by means of the via in the planarization layer. Then, a pixel definition layer is formed by means of a patterning process on the substrate on which the above structure is formed, wherein a pixel opening exposing the anode is formed in the pixel definition layer of each sub-pixel, and each pixel opening is used as a light emitting region of each sub-pixel.

Then, on the substrate on which the above structure is formed, a hole transport layer is formed by means of evaporation using an open mask, and then a connecting layer of the hole transport layers is formed on the display base plate, that is, the hole transport layers of all sub-pixels are connected. For example, the display base plate on which the anode and the pixel definition layer are formed are subjected to ultrasonic treatment in a cleaning agent, washed in deionized water, subjected to ultrasonic degreasing in an acetone-ethanol mixed solvent, and baked in a clean environment until water is completely removed. Then, the treated display base plate is placed in a vacuum chamber which is vacuumized to 1×10⁻⁵ to 1×10⁻⁶ Pa. The hole transport layer is formed by means of vacuum evaporation on an anode film layer, wherein an evaporation rate is about 0.1 nm/s, and an evaporation film has a thickness of about 100 nm.

Then, an electron blocking layer and a red light emitting layer, an electron blocking layer and a green light emitting layer, and an electron blocking layer and a blue light emitting layer are respectively formed on different sub-pixels by means of evaporation using a fine metal mask. The electron blocking layers and the emitting layers of adjacent sub-pixels may overlap for a small amount (for example, an overlap portion occupies less than 10% of the area of a respective light emitting layer pattern), or may be isolated from each other. In some examples, the red light emitting layer may include a phosphorescent guest material and a host material. The host material may be a conjugated condensed ring light emitting material, such as 4,4′-bis(9-carbazolyl)biphenyl or carbazole-triazine derivatives. The phosphorescent guest material may be an iridium complex or condensed ring complex, such as Ir(ppy)3, TBPe, or tris(2-phenylpyridine)iridium. In some examples, the thickness of the emitting layer ranges from about 10 nm to 50 nm.

Then, a hole blocking layer, an electron transporting layer, and a cathode are sequentially formed by means of evaporation using an open mask, and connecting layers of the hole blocking layers, the electron transporting layers, and the cathodes are formed on the display base plate, that is, the hole blocking layers of all sub-pixels are connected, the electron transporting layers of all sub-pixels are connected, and the cathodes of all sub-pixels are connected. In some examples, an evaporation rate of the hole blocking layer may be about 0.05 nm/s, and the film layer has a thickness of about 1 nm; an evaporation rate of the electron transporting layer is about 0.1 nm/s, and the film layer has a thickness of about 10 nm to 30 nm.

In some exemplary embodiments, an orthographic projection of one or more of the hole injection layer, the hole transport layer, the hole blocking layer, the electron transporting layer, the electron injection layer, and the cathode on the substrate is continuous. In some examples, regarding at least one row or column of sub-pixels, at least one of the hole injection layer, the hole transport layer, the hole blocking layer, the electron transporting layer, the electron injection layer, and the cathode of one sub-pixel is respectively connected to that of another sub-pixel. In some examples, regarding a plurality of sub-pixels, at least one of the hole injection layer, the hole transport layer, the hole blocking layer, the electron transporting layer, the electron injection layer, and the cathode of one sub-pixel is respectively connected to that of another sub-pixel.

Table 1 shows results of performance comparison between combination structures of several film layer materials according to this exemplary embodiment of the present disclosure. In the comparison experiment, structures of the organic light emitting layers of a comparison structure 1 and example structures 1 to 3 are all HTL/EBL/EML/HBL/ETL; the thicknesses of corresponding film layers of the comparison structure 1 and the example structures 1 to 3 are the same; and the materials of the emitting layers (EMLs), the materials of the hole blocking layers (HBLs), and the materials of the electron transporting layers (ETLs) of the comparison structure 1 and the example structures 1 to 3 are separately the same.

The related materials of the film layers of the same material in the comparison structure 1 and the example structures 1 to 3 are as follows:

| Item | Material |
|---|---|
| Emitting layer (EML) | Host material: |
| | 4,4′-bis(9-carbazolyl)biphenyl |
| | Guest material: TBPe |
| Hole blocking layer (HBL) | BCP |
| Electron transporting layer (ETL) | PBD |

The materials of the hole transport layers and the electron blocking layers of the comparison structure 1 and the example structures 1 to 3 are as follows:

| | Hole transport layer (HTL) | Electron blocking layer (EBL) |
|---|---|---|
| Comparison structure 1 | 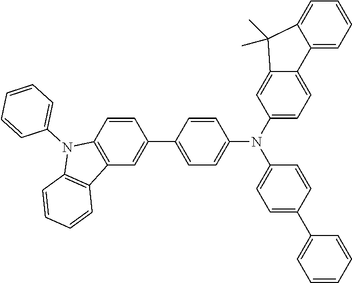 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] | 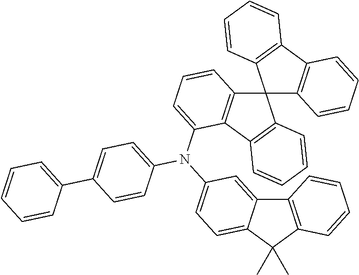 [SMILES: CC1(C)c2ccccc2-c2cc(N(c3ccc(-c4ccccc4)cc3)c3cccc4c3-c3ccccc3C43c4ccccc4-c4ccccc43)ccc21] |
| Example structure 1 | 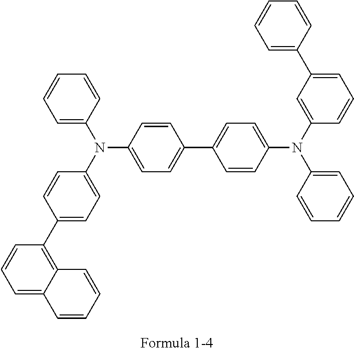 [SMILES: c1ccc(-c2cccc(N(c3ccccc3)c3ccc(-c4ccc(N(c5ccccc5)c5ccc(-c6cccc7ccccc67)cc5)cc4)cc3)c2)cc1] | 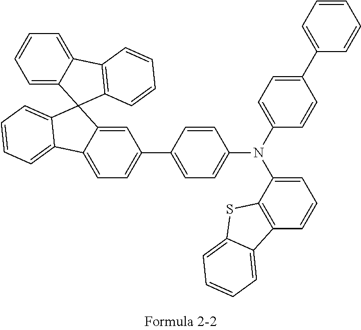 [SMILES: c1ccc(-c2ccc(N(c3ccc(-c4ccc5c(c4)C4(c6ccccc6-c6ccccc64)c4ccccc4-5)cc3)c3cccc4c3sc3ccccc34)cc2)cc1] |
| Example structure 2 | 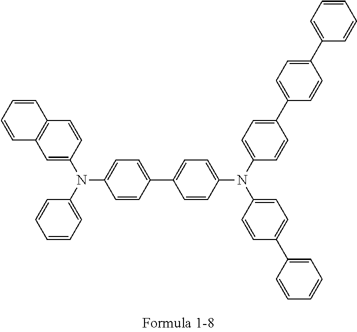 [SMILES: c1ccc(-c2ccc(-c3ccc(N(c4ccc(-c5ccccc5)cc4)c4ccc(-c5ccc(N(c6ccccc6)c6ccc7ccccc7c6)cc5)cc4)cc3)cc2)cc1] | 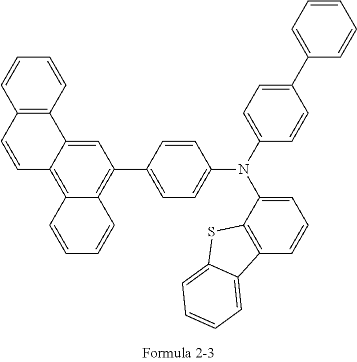 [SMILES: c1ccc(-c2ccc(N(c3ccc(-c4cc5c6ccccc6ccc5c5ccccc45)cc3)c3cccc4c3sc3ccccc34)cc2)cc1] |
| Example structure 3 | 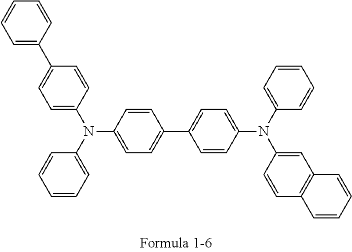 [SMILES: c1ccc(-c2ccc(N(c3ccccc3)c3ccc(-c4ccc(N(c5ccccc5)c5ccc6ccccc6c5)cc4)cc3)cc2)cc1] | 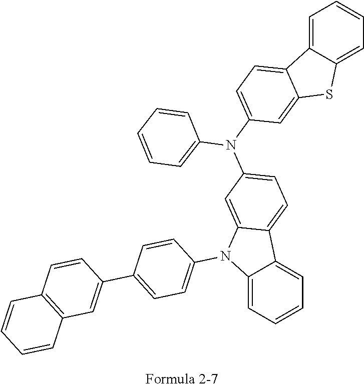 [SMILES: c1ccc(N(c2ccc3c(c2)sc2ccccc23)c2ccc3c4ccccc4n(-c4ccc(-c5ccc6ccccc6c5)cc4)c3c2)cc1] |

### Table 1 Results of Performance Comparison Between Different HTL and EBL Materials

| | Startup voltage (V) |
|---|---|
| Comparison structure 1 | 2.30 |
| Example structure 1 | 2.74 |
| Example structure 2 | 2.85 |
| Example structure 3 | 2.78 |

As shown in Table 1, compared with the comparison structure 1, the startup voltages of the example structures 1 to 3 are significantly increased. Therefore, in this exemplary embodiment, by adopting a combination of the materials of the hole transport layer and the electron blocking layer and by adjusting and controlling a difference between energy levels of the hole transport layer and the electron blocking layer, the startup voltage of the OLED can be effectively adjusted, for example, the startup voltage of the OLED can be effectively increased.

In some exemplary embodiments, the emitting layers of different colors of the display base plate have respective electron blocking layers. By configuring the combination of the materials of the hole transport layer and the electron blocking layer of the OLEDs of different colors, an energy level relationship between the hole transport layer and the electron blocking layer is adjusted, and the startup voltages of the OLEDs of different colors can be adjusted. For example, in the display base plate provided with light emitting devices of RGB three colors, by reasonably selecting the combination of the materials of the hole transport layer and the electron blocking layer and by configuring the energy level relationship between the hole transport layer and the electron blocking layer, the startup voltage of the red OLED can be improved.

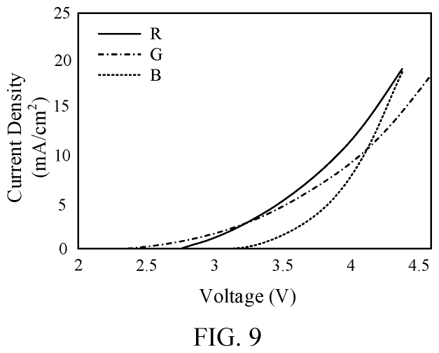

FIG. 9 is a curve graph of voltage-current densities of the light emitting devices of RGB three colors according to at least one embodiment of the present disclosure. In this exemplary embodiment, the structures of the organic light emitting layers of the red OLED, the green OLED, and the blue OLED are all HTL/EBL/EML/HBL/ETL. The materials of EMLs of the light emitting devices of RGB three colors are different. The EBLs of the light emitting devices of RGB three colors are independent of each other. The HTL and EBL of the red OLED may be made of the materials provided in this embodiment (for example, the material of the HTL has a structure represented by formula 1-1, and the material of the EBL has a structure represented by formula 2-1), and satisfy the energy level relationship in the above embodiment. Referring to FIG. 9, the startup voltage of the red OLED in this embodiment is between the startup voltage of the green OLED and the startup voltage of the blue OLED. In this embodiment, by increasing the startup voltage of the red OLED, the startup voltages of the OLEDs of RGB three colors can be balanced at the low gray tone, thereby effectively avoiding the low gray tone color cast (such as redness) phenomenon. In this example, the materials of the HTLs, the materials of the HBLs, and the materials of the ETLs of the blue OLED, the green OLED, and the red OLED may be separately the same. The EML of the blue OLED may be made of a blue light emitting material, and the EML of the green OLED may be made of a green light emitting material. The material of the EBL of the blue OLED and the material of the EBL of the green OLED may be different, and be different from the material of the EBL of the red OLED. However, this embodiment is not limited thereto. For example, the film layer structure and material of the green OLED may also refer to the design in this embodiment, so as to improve the startup voltage of the green OLED.

In this exemplary embodiment, by reasonably selecting the materials of the hole transport layer and the electron blocking layer and by configuring the energy level relationship between the hole transport layer and the electron blocking layer, the startup voltage of the OLED can be adjusted, so as to improve the display effect of the display device.

An embodiment of the present disclosure further provides a display device, including the organic light emitting device described above. The display device may be any product or component with a display function, such as a mobile phone, a tablet computer, a TV, a display, a notebook computer, a digital photo frame, a navigator, a vehicle-mounted display, a smart watch, or a smart wristband

In some exemplary embodiments, the display device includes a plurality of organic light emitting devices of different colors, and electron blocking layers of the plurality of organic light emitting devices are independent of each other. In this exemplary embodiment, by reasonably configuring a combination of materials of and an energy level relationship between a hole transport layer and an electron blocking layer of each of the organic light emitting devices of different colors, startup voltages of the organic light emitting devices of different colors can be balanced, so as to effectively avoid the low gray tone color cast phenomenon.

In some exemplary embodiments, the display device may include: a first organic light emitting device emitting red light, a second organic light emitting device emitting green light, and a third organic light emitting device emitting blue light. For example, the first organic light emitting device includes: a first electrode, a second electrode, and a hole injection layer, a hole transport layer, an electron blocking layer, a light emitting layer, a hole blocking layer, an electron transporting layer, and an electron injection layer which are sequentially disposed between the first electrode and the second electrode. The second organic light emitting device includes: a first electrode, a second electrode, and a hole injection layer, a hole transport layer, an electron blocking layer, a light emitting layer, a hole blocking layer, an electron transporting layer, and an electron injection layer which are sequentially disposed between the first electrode and the second electrode. The third organic light emitting device includes: a first electrode, a second electrode, and a hole injection layer, a hole transport layer, an electron blocking layer, a light emitting layer, a hole blocking layer, an electron transporting layer, and an electron injection layer which are sequentially disposed between the first electrode and the second electrode. The materials of the emitting layer, the emitting layer, and the emitting layer are different. The materials of the hole injection layers, the materials of the hole transport layers, the materials of the hole blocking layers, the materials of the electron transporting layers, and the materials of the electron injection layers of the first organic light emitting device to the third organic light emitting device may be separately the same. The materials of the electron blocking layers of the first organic light emitting device to the third organic light emitting device may be different. However, this embodiment is not limited thereto.

In some exemplary embodiments, the electromigration of the emitting layer of the third organic light emitting device is greater than the electromigration of the emitting layer of the first organic light emitting device, and the electromigration of the emitting layer of the first organic light emitting device is greater than the electromigration of the emitting layer of the second organic light emitting device. The hole mobility of the emitting layer of the second organic light emitting device is greater than the hole mobility of the emitting layer of the first organic light emitting device, and the hole mobility of the emitting layer of the first organic light emitting device is greater than the hole mobility of the emitting layer of the third organic light emitting device.

In some exemplary embodiments, the emitting layer of the first organic light emitting device has a thickness of about 30 nm to 45 nm. The emitting layer of the second organic light emitting device has a thickness of about 30 nm to 40 nm. The emitting layer of the third organic light emitting device has a thickness of about 20 nm to 35 nm.

In some exemplary embodiments, a drive voltage of the third organic light emitting device is greater than a drive voltage of the second organic light emitting device, and the drive voltage of the second organic light emitting device is greater than a drive voltage of the first organic light emitting device. The drive voltage is a working voltage of the organic light emitting device. For example, the drive voltage of the third organic light emitting device is about 2.8 V to 3.2 V, the drive voltage of the second organic light emitting device is about 2.6 V to 3.0 V, and the drive voltage of the first organic light emitting device is about 2.4 V to 3.0 V. However, this embodiment is not limited thereto.

In some exemplary embodiments, the luminance efficiency of the second organic light emitting device is greater than the luminance efficiency of the first organic light emitting device, and the luminance efficiency of the first organic light emitting device is greater than the luminance efficiency of the third organic light emitting device. For example, the luminance efficiency of the second organic light emitting device is about 130 cd/A to 150 cd/A, the luminance efficiency of the first organic light emitting device is about 70 cd/A to 100 cd/A, and the luminance efficiency of the third organic light emitting device is about 15 cd/A to 30 cd/A. However, this embodiment is not limited thereto.

In regard to the structures of the first organic light emitting device, the second organic light emitting device, and the third organic light emitting device in this embodiment, a reference may be made to the description of the organic light emitting device in the above embodiment, which is thus not described herein again.

Although the embodiments disclosed in the present disclosure are as described above, the content described is merely embodiment for facilitating the understanding of the present disclosure and is not used to limit the present disclosure. Those skilled in the art may make any modification and change in the form and details of the implementation without departing from the spirit and scope of the present disclosure. However, the scope of protection of the present disclosure should still be subject to the scope defined by the attached claims.

What is claimed is:

1. An organic light emitting device, comprising: a first electrode, a second electrode, and an emitting layer disposed between the first electrode and the second electrode, wherein
an electron blocking layer and a hole transport layer are disposed between the emitting layer and the first electrode; the electron blocking layer is located between the hole transport layer and the emitting layer;
the material of the electron blocking layer comprises a compound having the following structural formula: 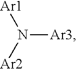
wherein Ar1 to Ar3 are separately one of a substituted or unsubstituted aryl group with 6 to 40 carbon atoms, a substituted or unsubstituted heteroaryl group with 3 to 40 carbon atoms, a substituted or unsubstituted alkyl group with 1 to 20 carbon atoms, and a substituted or unsubstituted cycloalkyl group with 1 to 30 carbon atoms;
at least one of Ar1 to Ar3 is connected to the following structure: 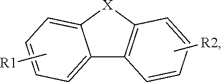
wherein X is one of carbon (C), nitrogen (N), sulfur (S), and oxygen (O);
R1 and R2 are separately one of hydrogen, deuterium, an alkyl group with 1 to 30 carbon atoms, a substituted or unsubstituted cycloalkyl group with 3 to 40 carbon atoms, a substituted or unsubstituted alkenyl group with 2 to 30 carbon atoms, a substituted or unsubstituted alkynyl group with 2 to 30 carbon atoms, a substituted or unsubstituted heteroalkyl group with 2 to 30 carbon atoms, a substituted or unsubstituted arylalkyl group with 7 to 30 carbon atoms, a substituted or unsubstituted aryl group with 6 to 30 carbon atoms, and a substituted or unsubstituted heteroaryl group with 2 to 30 carbon atoms; and
the material of the hole transport layer comprises a compound having the following structural formula: 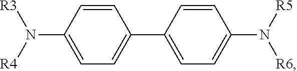
wherein R3 to R6 are separately one of deuterium, a cyano group, a nitro group, halogen, a hydroxyl group, a substituted or unsubstituted alkyl group with 1 to 30 carbon atoms, a substituted or unsubstituted cycloalkyl group with 1 to 20 carbon atoms, a substituted or unsubstituted alkenyl group with 2 to 30 carbon atoms, a substituted or unsubstituted alkynyl with 2 to 24 carbon atoms, a substituted or unsubstituted heteroalkyl group with 2 to 30 carbon atoms, a substituted or unsubstituted arylalkyl group with 7 to 30 carbon atoms, a substituted or unsubstituted aryl group with 6 to 30 carbon atoms, a substituted or unsubstituted heteroaryl group with 2 to 30 carbon atoms, a substituted or unsubstituted heteroaryl group with 3 to 30 carbon atoms, a substituted or unsubstituted alkoxy group with 1 to 30 carbon atoms, a substituted or unsubstituted alkylamino group with 1 to 30 carbon atoms, a substituted or unsubstituted arylamino group with 6 to 30 carbon atoms, a substituted or unsubstituted arylalkylamino group with 6 to 30 carbon atoms, a substituted or unsubstituted heteroarylamino group with 2 to 24 carbon atoms, a substituted or unsubstituted alkylmethylsilyl group with 1 to 30 carbon atoms, a substituted or unsubstituted arylmethylsilyl group with 6 to 30 carbon atoms, and a substituted or unsubstituted aryloxy group with 6 to 30 carbon atoms.

2. The organic light emitting device according to claim 1, wherein Ar1, Ar2, and Ar3 are at least partially the same or different from each other, and R1 and R2 are the same or different.

3. The organic light emitting device according to claim 1, wherein the electron blocking layer and the hole transport layer satisfy the following condition:
0.3 eV≤|HOMO_{EBL}|−|HOMO_{HTL}|≤0.7 eV,
wherein HOMO_{EBL} is the Highest Occupied Molecular Orbital (HOMO) energy level of the electron blocking layer, and HOMO_{HTL} is the HOMO energy level of the hole transport layer.

4. The organic light emitting device according to claim 3, wherein the HOMO energy level of the electron blocking layer is about −5.4 eV to −6.2 eV, and the HOMO energy level of the hole transport layer is about −5.3 eV to −5.6 eV.

5. The organic light emitting device according to claim 1, wherein the electron blocking layer and the hole transport layer further satisfy the following condition:
0.3 eV≤LUMO_{HTL}−LUMO_{EBL}≤0.8 eV,
wherein LUMO_{EBL} is the Lowest Unoccupied Molecular Orbital (LUMO) energy level of the electron blocking layer, and LUMO_{HTL} is the LUMO energy level of the hole transport layer.

6. The organic light emitting device according to claim 5, wherein the LUMO energy level of the electron blocking layer is about −2.2 eV to −2.4 eV, and the LUMO energy level of the hole transport layer is about −2.2 eV to −2.5 eV.

7. The organic light emitting device according to claim 1, wherein the material of the electron blocking layer comprises one or more of compounds having the following structural formulas:

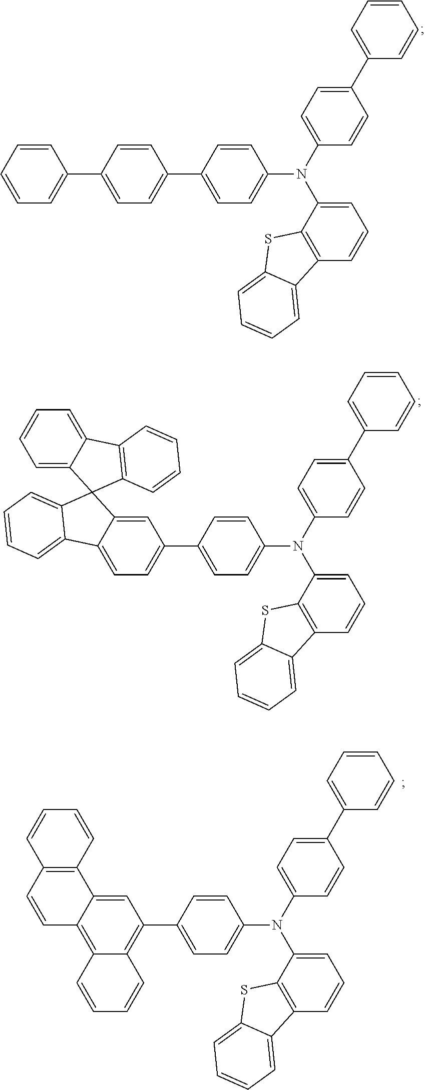 [SMILES: c1ccc(-c2ccc(-c3ccc(N(c4ccc(-c5ccccc5)cc4)c4cccc5c4sc4ccccc45)cc3)cc2)cc1 ; c1ccc(-c2ccc(N(c3ccc(-c4ccc5c(c4)C4(c6ccccc6-c6ccccc64)c4ccccc4-5)cc3)c3cccc4c3sc3ccccc34)cc2)cc1 ; c1ccc(-c2ccc(N(c3ccc(-c4cc5c6ccccc6ccc5c5ccccc45)cc3)c3cccc4c3sc3ccccc34)cc2)cc1]

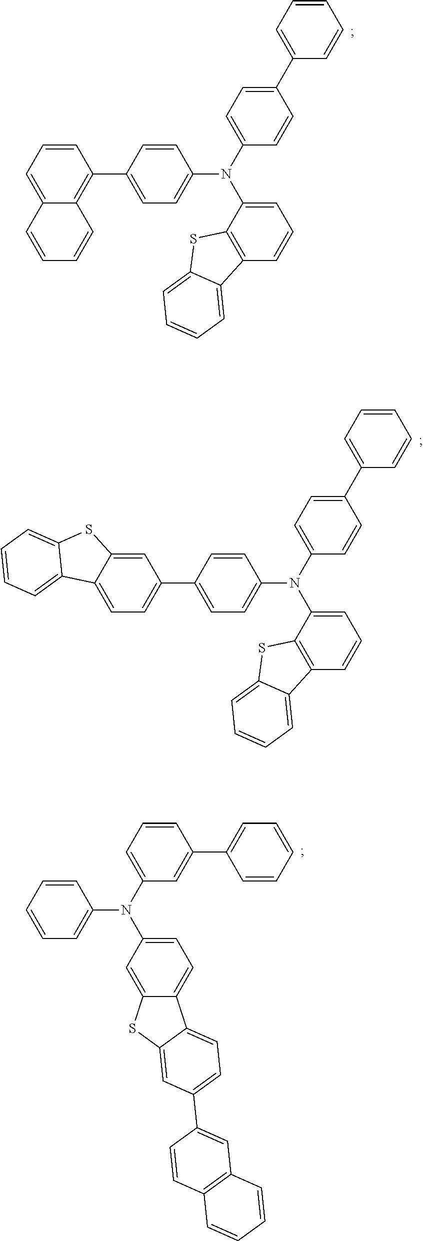 [SMILES: c1ccc(-c2ccc(N(c3ccc(-c4cccc5ccccc45)cc3)c3cccc4c3sc3ccccc34)cc2)cc1 ; c1ccc(-c2ccc(N(c3ccc(-c4ccc5c(c4)sc4ccccc45)cc3)c3cccc4c3sc3ccccc34)cc2)cc1 ; c1ccc(-c2cccc(N(c3ccccc3)c3ccc4c(c3)sc3cc(-c5ccc6ccccc6c5)ccc34)c2)cc1]

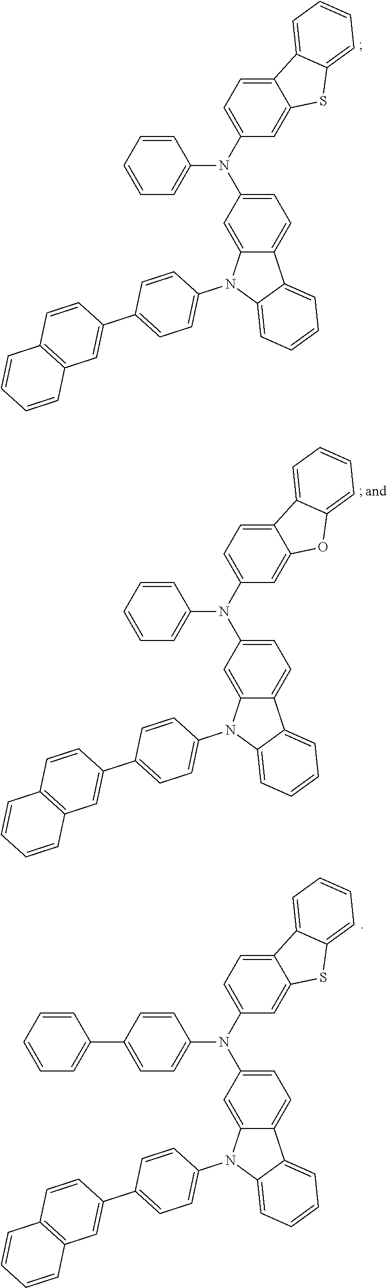 [SMILES: c1ccc(N(c2ccc3c(c2)sc2ccccc23)c2ccc3c4ccccc4n(-c4ccc(-c5ccc6ccccc6c5)cc4)c3c2)cc1 ; c1ccc(N(c2ccc3c(c2)oc2ccccc23)c2ccc3c4ccccc4n(-c4ccc(-c5ccc6ccccc6c5)cc4)c3c2)cc1 ; c1ccc(-c2ccc(N(c3ccc4c(c3)sc3ccccc34)c3ccc4c5ccccc5n(-c5ccc(-c6ccc7ccccc7c6)cc5)c4c3)cc2)cc1]

8. The organic light emitting device according to claim 1, wherein the material of the hole transport layer comprises one or more of compounds having the following structural formulas:

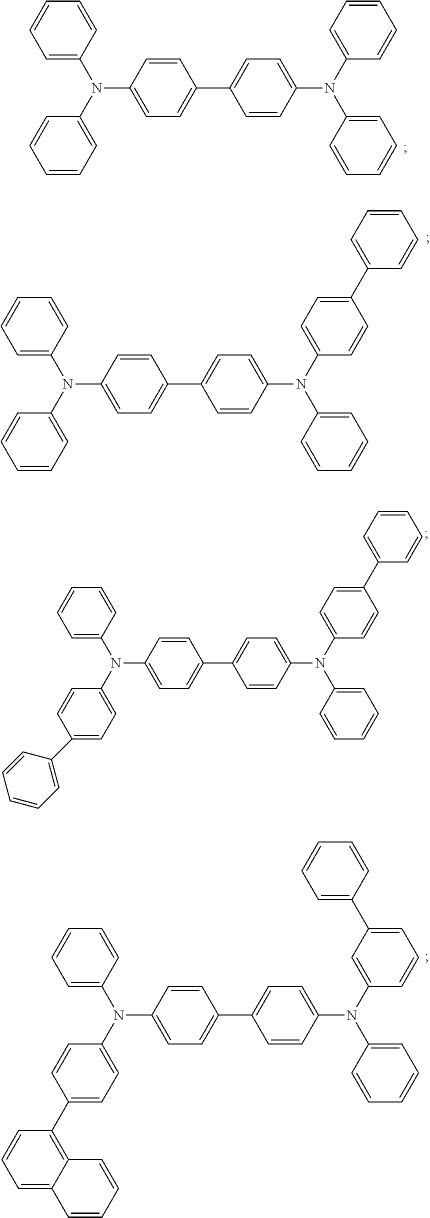

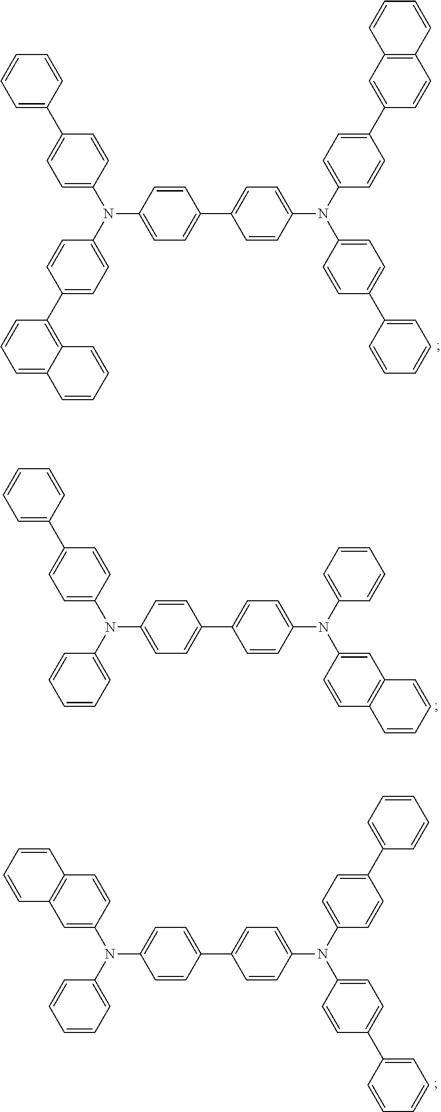 [SMILES: c1ccc(-c2ccc(N(c3ccc(-c4ccc(N(c5ccc(-c6ccccc6)cc5)c5ccc(-c6cccc7ccccc67)cc5)cc4)cc3)c3ccc(-c4ccc5ccccc5c4)cc3)cc2)cc1 ; c1ccc(-c2ccc(N(c3ccccc3)c3ccc(-c4ccc(N(c5ccccc5)c5ccc6ccccc6c5)cc4)cc3)cc2)cc1 ; c1ccc(-c2ccc(N(c3ccc(-c4ccccc4)cc3)c3ccc(-c4ccc(N(c5ccccc5)c5ccc6ccccc6c5)cc4)cc3)cc2)cc1]

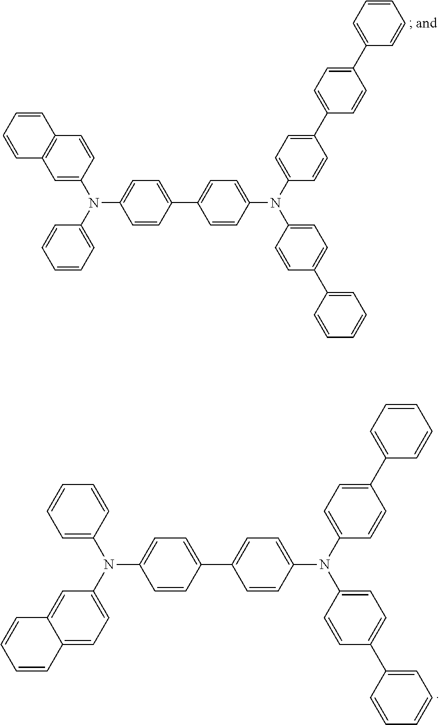 [SMILES: c1ccc(-c2ccc(-c3ccc(N(c4ccc(-c5ccccc5)cc4)c4ccc(-c5ccc(N(c6ccccc6)c6ccc7ccccc7c6)cc5)cc4)cc3)cc2)cc1 ; c1ccc(-c2ccc(N(c3ccc(-c4ccccc4)cc3)c3ccc(-c4ccc(N(c5ccccc5)c5ccc6ccccc6c5)cc4)cc3)cc2)cc1]

9. The organic light emitting device according to claim 1, wherein the emitting layer is a red light emitting layer.

10. The organic light emitting device according to claim 1, wherein the electron blocking layer has a thickness of about 3 nm to 10 nm.

11. A display device, comprising the organic light emitting device according to claim 1.

12. The display device according to claim 11, wherein the display device comprises a plurality of organic light emitting devices of different colors, and electron blocking layers of the plurality of organic light emitting devices are independent of each other.

13. The display device according to claim 12, wherein the display device comprises: a first organic light emitting device emitting red light, a second organic light emitting device emitting green light, and a third organic light emitting device emitting blue light.

14. The display device according to claim 13, wherein
the electromigration of an emitting layer of the third organic light emitting device is greater than the electromigration of an emitting layer of the first organic light emitting device, and the electromigration of the emitting layer of the first organic light emitting device is greater than the electromigration of an emitting layer of the second organic light emitting device; and
the hole mobility of the emitting layer of the second organic light emitting device is greater than the hole mobility of the emitting layer of the first organic light emitting device, and the hole mobility of the emitting layer of the first organic light emitting device is greater than the hole mobility of the emitting layer of the third organic light emitting device.

15. The display device according to claim 13, wherein a startup voltage of the third organic light emitting device is greater than a startup voltage of the first organic light emitting device, and the startup voltage of the first organic light emitting device is greater than a startup voltage of the second organic light emitting device.

16. The display device according to claim 13, wherein the luminance efficiency of the second organic light emitting device is greater than the luminance efficiency of the first organic light emitting device, and the luminance efficiency of the first organic light emitting device is greater than the luminance efficiency of the third organic light emitting device.

17. The organic light emitting device according to claim 2, wherein the electron blocking layer and the hole transport layer further satisfy the following condition:
0.3 eV≤LUMO_{HTL}−LUMO_{EBL}≤0.8 eV,
wherein LUMO_{EBL} is the Lowest Unoccupied Molecular Orbital (LUMO) energy level of the electron blocking layer, and LUMO_{HTL} is the LUMO energy level of the hole transport layer.

18. The organic light emitting device according to claim 3, wherein the electron blocking layer and the hole transport layer further satisfy the following condition:
0.3 eV≤LUMO_{HTL}−LUMO_{EBL}≤0.8 eV,
wherein LUMO_{EBL} is the Lowest Unoccupied Molecular Orbital (LUMO) energy level of the electron blocking layer, and LUMO_{HTL} is the LUMO energy level of the hole transport layer.

19. The organic light emitting device according to claim 4, wherein the electron blocking layer and the hole transport layer further satisfy the following condition:
0.3 eV≤LUMO_{HTL}−LUMO_{EBL}≤0.8 eV,
wherein LUMO_{EBL} is the Lowest Unoccupied Molecular Orbital (LUMO) energy level of the electron blocking layer, and LUMO_{HTL} is the LUMO energy level of the hole transport layer.

20. A display device, comprising the organic light emitting device according to claim 2.
